(19) United States
(12) Patent Application Publication
(10) Pub. No.: US 2017/0098786 A1
(43) Pub. Date: Apr. 6, 2017

(54) COMPOSITION FOR FORMING ORGANIC SEMICONDUCTOR FILM, ORGANIC SEMICONDUCTOR FILM AND METHOD FOR MANUFACTURING SAME, ORGANIC SEMICONDUCTOR ELEMENT AND METHOD FOR MANUFACTURING SAME, AND ORGANIC SEMICONDUCTOR COMPOUND

(71) Applicant: FUJIFILM CORPORATION, Tokyo (JP)

(72) Inventors: Tetsu KITAMURA, Kanagawa (JP); Masashi KOYANAGI, Kanagawa (JP); Yuta SHIGENOI, Kanagawa (JP)

(21) Appl. No.: 15/382,745

(22) Filed: Dec. 19, 2016

Related U.S. Application Data
(63) Continuation of application No. PCT/JP2015/074027, filed on Aug. 26, 2015.

(30) Foreign Application Priority Data
Sep. 1, 2014 (JP) 2014-177324

(51) Int. Cl. H01L 51/00; C09D 5/24

(52) U.S. Cl. CPC H01L 51/0074; C09D 5/24; H01L 51/0068; H01L 51/0094; H01L 51/0073; H01L 51/0055; H01L 51/0005; H01L 51/0004; H01L 51/0566

(57) ABSTRACT

Objects of the present invention are to provide a composition for forming an organic semiconductor film that has excellent preservation stability and makes the obtained organic semiconductor element exhibit excellent driving stability in the atmosphere, to provide an organic semiconductor film using the composition for forming an organic semiconductor film, a method for manufacturing the organic semiconductor film, an organic semiconductor element, a method for manufacturing the organic semiconductor element, and to provide a novel organic semiconductor compound.

A composition for forming an organic semiconductor film of the present invention contains a specific organic semiconductor having an alkoxyalkyl group as a component A and a solvent as a component B, in which a content of a non-halogen-based solvent is equal to or greater than 50% by mass with respect to a total content of the component B, and a content of the component A is equal to or greater than 0.7% by mass and less than 15% by mass.

### CROSS-REFERENCE TO RELATED APPLICATIONS

This application is a continuation application of International Application No. PCT/JP2015/074027, filed Aug. 26, 2015, the disclosure of which is incorporated herein by reference in its entirety. Further, this application claims priority from Japanese Patent Application No. 2014-177324, filed Sep. 1, 2014, the disclosure of which is incorporated herein by reference in its entirety.

### BACKGROUND OF THE INVENTION

1. Field of the Invention

The present invention relates to a composition for forming an organic semiconductor film, an organic semiconductor film and a method for manufacturing the same, an organic semiconductor element and a method for manufacturing the same, and an organic semiconductor compound.

2. Description of the Related Art

An organic transistor having an organic semiconductor film (organic semiconductor layer) is used in a field effect transistor (FET) used in a liquid crystal display or an organic EL display, a Radio Frequency Identifier (RFID, RF tag), and the like, because the use of the organic transistor makes it possible to achieve lightening of weight and cost reduction and to achieve flexibilization.

As organic semiconductors of the related art, those described in JP2009-267132A and JP2012-510454A are known.

### SUMMARY OF THE INVENTION

An object of the present invention is to provide a composition for forming an organic semiconductor film that has excellent preservation stability and makes the obtained organic semiconductor element exhibit excellent driving stability in the atmosphere. Another object of the present invention is to provide an organic semiconductor film using the composition for forming an organic semiconductor film, a method for manufacturing the organic semiconductor film, an organic semiconductor element, and a method for manufacturing the organic semiconductor element. Still other object of the present invention is to provide a novel organic semiconductor compound.

The aforementioned objects of the present invention were achieved by means described in the following <1>, <13> to <15>, <17>, and <18>. Preferred embodiments are also described in the following <2> to <12>, <16>, and <19> to <21>.

<1> A composition for forming an organic semiconductor film, comprising an organic semiconductor represented by the following Formula A-1 as a component A and a solvent as a component B, in which a content of a non-halogen-based solvent is equal to or greater than 50% by mass with respect to a total content of the component B, and a content of the component A is equal to or greater than 0.7% by mass and less than 15% by mass.

TLₘ-Z)ₙ (A-1)

In Formula A-1, T represents an aromatic hydrocarbon group having a ring-fused structure including 3 or more rings or a heteroaromatic group; L each independently represents a phenylene group or a thienylene group; Z each independently represents a group represented by the following Formula a-1; m each independently represents an integer of 0 to 4, and n represents an integer of 1 to 8; and in a case where T does not have a ring-fused structure including 5 or more rings, that is, in a case where T is a group having a ring-fused structure including 3 or 4 rings, m represents an integer of 1 to 4, and n represents an integer of 2 to 8.

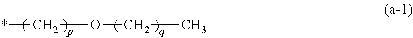

In Formula a-1, p represents an integer of 1 to 20, q represents an integer of 0 to 20, and * represents a binding position with respect to other structures.

<2> The composition for forming an organic semiconductor film described in <1>, in which in Formula A-1, T contains an acene, phenacene, or heteroacene skeleton having a ring-fused structure including 3 to 7 rings.

<3> The composition for forming an organic semiconductor film described in <1> or <2>, in which the component A is an organic semiconductor represented by the following Formula A-2.

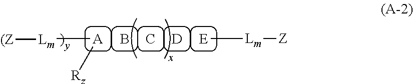

In Formula A-2, rings A to E each independently represent a benzene ring or a thiophene ring; R represents an alkyl group, an alkenyl group, an alkynyl group, an aromatic hydrocarbon group, an aromatic heterocyclic group, or a fluorine atom; L each independently represents a phenylene group or a thienylene group; Z each independently represents a group represented by Formula a-1; m each independently represents an integer of 0 to 4; when there are two or more L's, L's may be the same as or different from each other; when there are two or more Z's, Z's may be the same as or different from each other, x represents an integer of 1 to 3; y represents 0 or 1; z represents 0 or 1; and the symmetry of a ring-fused structure formed of the rings A to E is C₂, C₂ᵥ, or C₂ₕ.

<4> The composition for forming an organic semiconductor film described in <3>, in which 2 to 4 rings among the rings A to E are thiophene rings.

<5> The composition for forming an organic semiconductor film described in <3> or <4>, in which the rings A and E are thiophene rings and/or L is a thienylene group, and m is an integer of 1 to 4.

<6> The composition for forming an organic semiconductor film described in any one of <1> to <5>, in which in Formula a-1, p is an integer of 1 to 6.

<7> The composition for forming an organic semiconductor film described in any one of <1> to <6>, in which a boiling point of the non-halogen-based solvent is equal to or higher than 100° C.

<8> The composition for forming an organic semiconductor film described in any one of <1> to <7>, in which the non-halogen-based solvent contains an aromatic solvent in an amount of equal to or greater than 50% by mass.

<9> The composition for forming an organic semiconductor film described in any one of <1> to <8> that has a viscosity of equal to or higher than 5 mPa·s and equal to or lower than 40 mPa·s at 25° C.

<10> The composition for forming an organic semiconductor film described in any one of <1> to <9>, further comprising a binder polymer as a component C.

<11> The composition for forming an organic semiconductor film described in any one of <1> to <10>, in which a concentration of total solid content is equal to or higher than 1.5% by mass.

<12> The composition for forming an organic semiconductor film described in any one of <1> to <11> that is used for ink jet printing and/or flexographic printing.

<13> A method for manufacturing an organic semiconductor film, comprising an application step of applying the composition for forming an organic semiconductor film described in any one of <1> to <12> onto a substrate, and a drying step of removing a solvent from the applied composition.

<14> An organic semiconductor film obtained by the method described in <13>.

<15> A method for manufacturing an organic semiconductor element, comprising an application step of applying the composition for forming an organic semiconductor film described in any one of <1>to <12>onto a substrate, and a drying step of removing a solvent from the applied composition.

<16> The method for manufacturing an organic semiconductor element described in <15>, in which the application step is performed by ink jet printing or flexographic printing.

<17> An organic semiconductor element obtained by the method described in <15> or <16>.

<18> An organic semiconductor compound represented by Formula A-2.

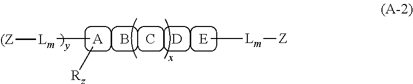

In Formula A-2, rings A to E each independently represent a benzene ring or a thiophene ring; R represents an alkyl group, an alkenyl group, an alkynyl group, an aromatic hydrocarbon group, an aromatic heterocyclic group, or a fluorine atom; L each independently represents a phenylene group or a thienylene group; Z each independently represents a group represented by the following Formula a-1; m each independently represents an integer of 0 to 4; when there are two or more L's, L's may be the same as or different from each other; when there are two or more Z's, Z's may be the same as or different from each other; x represents an integer of 1 to 3; y represents 0 or 1; z represents 0 or 1; and the symmetry of a ring-fused structure formed of the rings A to E is C₂, C₂ᵥ, or C₂ₕ.

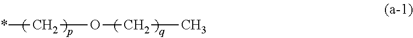

In Formula a-1, p represents an integer of 1 to 20, q represents an integer of 0 to 20, and * represents a binding position with respect to other structures.

<19> The organic semiconductor compound described in <18>, in which 2 to 4 rings among the rings A to E are thiophene rings.

<20> The organic semiconductor compound described in <18> or <19>, in which the rings A and E are thiophene rings and/or L is a thienylene group, and m is an integer of 1 to 4.

<21> The organic semiconductor compound described in any one of <18> to <20>, in which in Formula a-1, p is an integer of 1 to 6.

According to the present invention, it is possible to provide a composition for forming an organic semiconductor film that has excellent preservation stability and makes the obtained organic semiconductor element exhibit excellent driving stability in the atmosphere. Furthermore, according to the present invention, it is possible to provide an organic semiconductor film using the composition for forming an organic semiconductor film, a method for manufacturing the organic semiconductor film, an organic semiconductor element, and a method for manufacturing the organic semiconductor element. In addition, according to the present invention, it is possible to provide a novel organic semiconductor compound.

### BRIEF DESCRIPTION OF THE DRAWINGS

FIG. 1 is a schematic cross-sectional view of an aspect of an organic semiconductor element of the present invention.

FIG. 2 is a schematic cross-sectional view of another aspect of the organic semiconductor element of the present invention.

FIG. 3 is a plan view of a metal mask used in examples.

### DESCRIPTION OF THE PREFERRED EMBODIMENTS

Hereinafter, the contents of the present invention will be specifically described. The constituents in the following description will be explained based on typical embodiments of the present invention, but the present invention is not limited to the embodiments. In the specification of the present application, “to” is used to mean that the numerical values listed before and after “to” are a lower limit and an upper limit respectively. Furthermore, in the present invention, an organic EL element refers to an organic electroluminescence element.

In the present specification, in a case where there is no description regarding whether a group (atomic group) is substituted or unsubstituted, the group includes both of a group having a substituent and a group not having a substituent. For example, an “alkyl group” includes not only an alkyl group not having a substituent (unsubstituted alkyl group) but also an alkyl group having a substituent (substituted alkyl group).

In the present specification, in some cases, a chemical structural formula is described as a simplified structural formula in which a hydrogen atom is omitted.

In the present invention, “mobility” refers to “carrier mobility” and means either of both of electron mobility and hole mobility.

In the present invention, “% by mass” and “% by weight” have the same definition, and “part by mass” and “part by weight” have the same definition.

In the present invention, a combination of preferred aspects is more preferable.

(Composition for Forming Organic Semiconductor Film and Organic Semiconductor Compound)

A composition for forming an organic semiconductor film of the present invention contains an organic semiconductor represented by Formula A-1 as a component A and a solvent as a component B, in which a content of a non-halogen-based solvent is equal to or greater than 50% by mass with respect to a total content of the component B, and a content of the component A is equal to or greater than 0.7% by mass and less than 15% by mass.

As a result of repeating intensive investigation, the inventors of the present invention obtained knowledge that, by using a composition for forming an organic semiconductor film containing the aforementioned components A and B, excellent preservation stability of a composition for forming an organic semiconductor film can be obtained, and the obtained organic semiconductor film or organic semiconductor element exhibits high driving stability in the atmosphere. Based on the knowledge, the inventors accomplished the present invention.

The inventors of the present invention found that, if a halogen-based solvent is used as a solvent, the solubility of an organic semiconductor compound becomes excellent, but the obtained organic semiconductor film or organic semiconductor element exhibits low driving stability.

A detailed mechanism that brings about such effects is unclear. Presumably, because the component A has an alkoxyalkyl group (group represented by Z) on a terminal thereof, the solubility of the component A in a non-halogen-based solvent may be improved, and the preservation stability may become excellent. Furthermore, presumably, because the composition for forming an organic semiconductor film is a composition in which the use of a non-halogen-based solvent is suppressed, the driving stability of the obtained organic semiconductor film or organic semiconductor element in the atmosphere may be improved.

Hereinafter, each component used in the composition for forming an organic semiconductor film of the present invention will be described.

Component A: Compound Represented by Formula A-1

The composition for forming an organic semiconductor film of the present invention contains a compound represented by the following Formula A-1 (hereinafter, referred to as a “specific compound” as well).

TLₘ-Z)ₙ (A-1)

In Formula A-1, T represents an aromatic hydrocarbon group having a ring-fused structure including 3 or more rings or a heteroaromatic group, L each independently represents a phenylene group or a thienylene group, Z each independently represents a group represented by the following Formula a-1, m each independently represents an integer of 0 to 4, and n represents an integer of 1 to 8. In a case where T is a group having a ring-fused structure including 3 or 4 rings, m represents an integer of 1 to 4, and n represents an integer of 2 to 8.

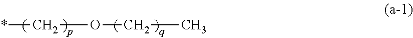

In Formula a-1, p represents an integer of 1 to 20, q represents an integer of 0 to 20, and * represents a binding position with respect to other structures.

The component A can be suitably used in an organic semiconductor element, an organic semiconductor film, and a composition for forming an organic semiconductor film.

The component A is a compound in which an alkoxyalkyl group (Z) represented by Formula a-1 is bonded to an organic semiconductor mother nucleus (T) through a linking group (L) as necessary, and the linking group is selected from the group consisting of a phenylene group, a thienylene group, and a group in which plural phenylene groups or thienylene groups are bonded to each other.

In Formula A-1, T represents an aromatic hydrocarbon group having a ring-fused structure including 3 or more rings or a heteroaromatic group (aromatic heterocyclic group). T is a group obtained by the fusion of 3 or more aromatic rings and exhibits aromaticity. Examples of the aromatic ringS include an aromatic hydrocarbon ring (for example, a benzene ring), and an aromatic heterocyclic ring (for example, a thiophene ring, a furan ring, a pyrrole ring, a selenophene ring, or an imidazole ring).

T has a ring-fused structure including 3 or more rings. From the viewpoint of the mobility of an organic semiconductor, T preferably includes 3 to 9 rings, more preferably includes 3 to 7 rings, and even more preferably includes 3 to 6 rings.

It is preferable that at least one of the aromatic rings included in T is preferably an aromatic heterocyclic ring. It is more preferable that the aromatic rings contain, as a heteroatom, at least one kind of atom selected from the group consisting of a sulfur atom, a nitrogen atom, a selenium atom, and an oxygen atom. From the viewpoint of the mobility of an organic semiconductor, the aforementioned heteroatom is more preferably contained in 2 to 6 rings, and even more preferably contained in 2 to 4 rings.

From the viewpoint of the mobility of an organic semiconductor, the aforementioned aromatic heterocyclic ring preferably contain one heteroatom.

Furthermore, from the viewpoint of mobility of an organic semiconductor, T preferably has at least a thiophene ring structure and/or a selenophene ring structure, more preferably has at least a thiophene ring structure. It is even more preferable that all of the heterocyclic structures that T has are thiophene rings structures.

The compound represented by Formula A-1 contains a group represented by T, and the group is contained in the compound as a main component (main partial structure). Herein, the “main component” means that a molecular weight-based content of a ring-fused polycyclic aromatic group is equal to or greater than 30% with respect to a total molecular weight of the compound represented by Formula A-1. The content is preferably equal to or greater than 40%. An upper limit of the content is not particularly limited, but from the viewpoint of solubility, the upper limit is preferably equal to or less than 80%.

In Formula A-1, T is preferably a structure in which aromatic heterocyclic rings and/or benzene rings are fused with each other in the form of a line (including a straight-line shape and a zigzag pattern). T more preferably contains an acene, phenacene, or heteroacene structure having a ring-fused structure including 3 to 7 rings. Acene is a compound in which benzene rings are liearly fused with each other such that an angle formed between the benzene rings becomes 180° . Specific examples thereof include naphthalene, anthracene, tetracene, pentacene, hexacene, heptacene, and the like. Phenacene is a compound in which benzene rings are fused with each other in a zigzag pattern, and specific examples thereof include phenanthrene, chrysene, picene, and the like. Heteroacene means a compound obtained by substituting some of benzene rings of acene or phene with an aromatic heterocyclic ring (for example, a furan ring, a thiophene ring, or a pyrrole ring). Phene is a compound in which benzene rings are fused in patterns including a zigzag pattern, and all of the phenacenes having a zigzag structure are included in phene. Specific examples of hydrocarbons which are included in phene but are not included in phenacene include benzo[a] anthracene, benzo[c] phenanthrene, dibenzo[a,h] anthracene, dibenzo[a,j] anthracene, dibenzo[c,g] phenanthrene, pentaphene, and the like.

In the specific compound, T as an organic semiconductor mother nucleus contains a heteroacene skeleton in which aromatic heterocyclic rings and/or benzene rings are linearly fused with each other. T is more preferably a thienoacene structure in which thiophene rings and/or benzene rings are linearly fused with each other, and even more preferably a thienoacene structure including 3 to 7 rings fused with each other. If the aforementioned aspect is adopted, an organic semiconductor layer or film having higher mobility is obtained.

From the viewpoint of the mobility of an organic semiconductor, the number of thiophene rings in the fused polycyclic aromatic group is preferably 2 to 7, more preferably 3 to 7, even more preferably 3 to 5, and particularly preferably 3.

The aromatic hydrocarbon group or the heteroaromatic group having the ring-fused structure that T has may have a substituent other than-Lₘ-Z.

Examples of the substituent include a halogen atom, an alkyl group (including a cycloalkyl group, a bicycloalkyl group, and a tricycloalkyl group), an alkenyl group, an alkynyl group, an aryl group, a heterocyclic group (may be referred to as a hetero ring group as well), a cyano group, a hydroxy group, a nitro group, a carboxy group, an alkoxy group, an aryloxy group, a silyloxy group, a heterocyclic oxy group, an acyloxy group, a carbamoyloxy group, an alkoxycarbonyloxy group, an aryloxycarbonyloxy group, an amino group (including an anilino group), an ammonio group, an acylamino group, an aminocarbonylamino group, alkoxycarbonylamino group, an aryloxycarbonylamino group, a sulfamoylamino group, alkyl-and arylsulfonylamino groups, a mercapto group, an alkylthio group, an arylthio group, a heterocyclic thio group, a sulfamoyl group, a sulfo group, alkyl-and arylsulfinyl groups, alkyl-and arylsulfonyl groups, an acyl group, an aryloxycarbonyl group, an alkoxycarbonyl group, a carbamoyl group, aryl- and heterocyclic azo groups, an imide group, a phosphino group, a phosphinyl group, a phosphinyloxy group, a phosphinylamino group, a phosphono group, a silyl group (a trialkylsilyl group or the like), a hydrazino group, a ureido group, a boronic acid group (—B(OH)₂), a phosphato group (—OPO(OH)₂), a sulfato group (—OSO₃H), and other known substituents. These substituents may be further substituted with a substituent.

Among these, as the substituent, a halogen atom, an alkyl group, an alkynyl group, an alkenyl group, an alkoxy group, an alkylthio group, and an aryl group are preferable, a fluorine atom, a substituted or unsubstituted alkyl group having 1 to 3 carbon atoms, a substituted or unsubstituted alkoxy group having one or two carbon atoms, a substituted or unsubstituted methylthio group, and a phenyl group are more preferable, and a fluorine atom, a substituted or unsubstituted alkyl group having 1 to 3 carbon atoms, a substituted or unsubstituted alkoxy group having one or two carbon atoms, and a substituted or unsubstituted methylthio group are particularly preferable.

Specific examples of the organic semiconductor mother nucleus represented by T in Formula A-1 preferably include the following fused polycyclic aromatic groups. In these fused polycyclic aromatic groups, the aforementioned substituent other than -Lₘ-Z may be bonded onto an aromatic ring and/or an aromatic heterocyclic ring.

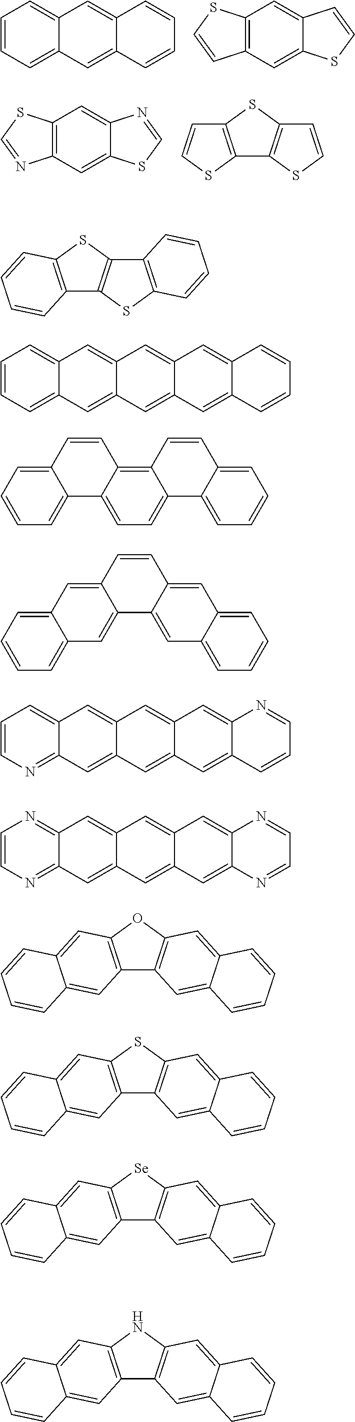

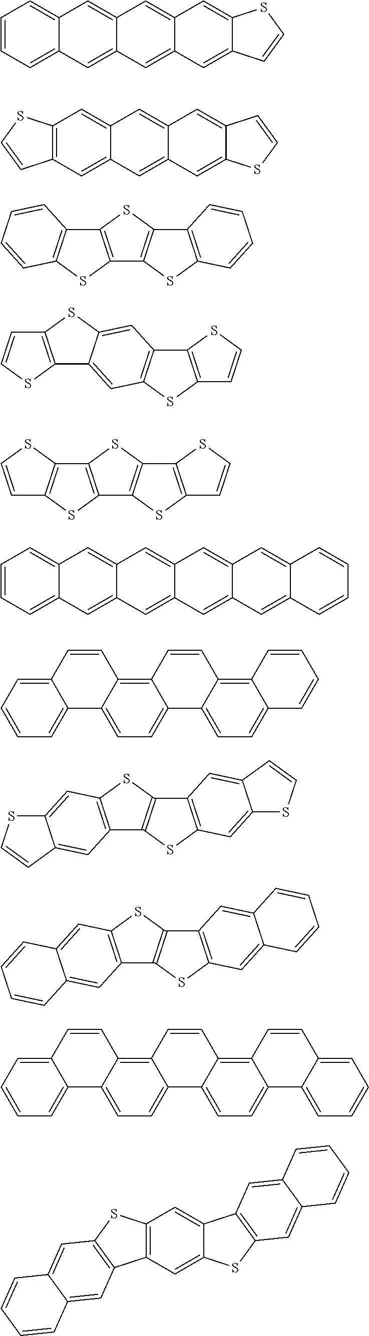

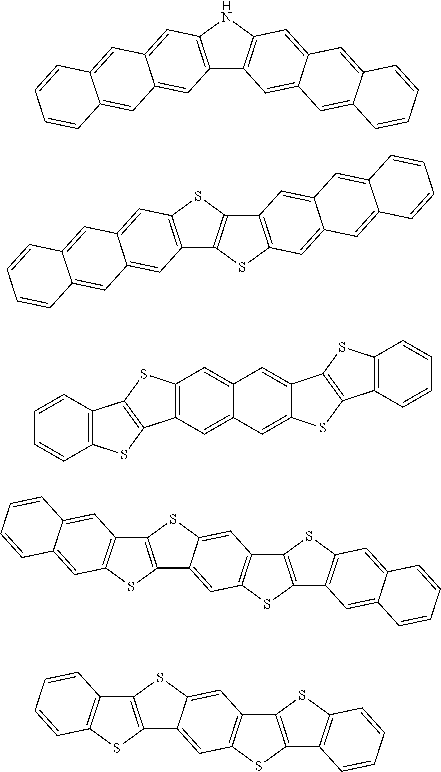

Among the above specific example, the structure in which thiophene rings are fused with each other and the structure in which thiophene rings and benzene rings are fused with each other are thioacene structures.

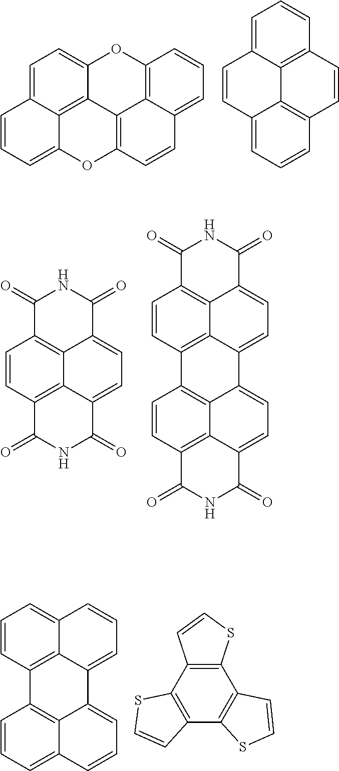

In Formula A-1, L each independently represents a phenylene group or a thienylene group. The thienylene group is a group obtained by removing two hydrogen atoms from thiophene. When m is equal to or greater than 2 and/or n is equal to or greater than 2, a plurality of L's may be the same as or different from each other. The phenylene group is preferably bonded to T and L or Z in a para-position. The thienylene group is preferably bonded to T and L or Z in a 2-position and a 5-position.

In Formula A-1, m represents an integer of 0 to 4. In a case where T does not have a ring-fused structure including 5 or more rings, that is, in a case where T is a group having a ring-fused structure including 3 or 4 rings, m represents an integer of 1 to 4. m is preferably an integer of 1 to 3, more preferably 1 or 2, and even more preferably 1. In a case where T does not have a ring-fused structure including 5 or more rings, if m is 0, the mobility is low, and sufficient driving stability is not obtained.

In a case where T has a ring-fused structure including 5 or more rings, m represents an integer of 0 to 4. m is preferably an integer of 0 to 2, more preferably 0 or 1, and even more preferably 0.

In Formula A-1, Z represents a group represented by Formula a-1 described above. That is, Z represents an alkoxyalkyl group. p represents an integer of 1 to 20. p is preferably an integer of 1 to 16, more preferably an integer of 1 to 8, and even more preferably an integer of 1 to 6.

q represents an integer of 0 to 20. q is preferably an integer of 0 to 16, more preferably an integer of 0 to 8, and even more preferably an integer of 0 to 6.

In Formula A-1, n represents an integer of 1 to 8. n is the number of -Lₘ-Z's substituting T. In a case where T does not have a ring-fused structure including 5 or more rings, that is, in a case where T is a group having a ring-fused structure including 3 or 4 rings, n represents an integer of 2 to 8. n is preferably an integer of 2 to 6, more preferably an integer of 2 to 4, and even more preferably 2. In a case where T does not have a ring-fused structure including 5 or more rings, if n is 1, sufficient driving stability is not obtained.

In a case where T has a ring-fused structure including 5 or more rings, n represents an integer of 1 to 8. n is preferably an integer of 1 to 4, more preferably 1 or 2, and even more preferably 2.

The component A is preferably a compound represented by the following Formula A-2, and an organic semiconductor compound of the present invention is the compound represented by the following Formula A-2.

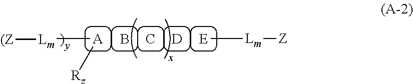

In Formula A-2, rings A to E each independently represent a benzene ring or a thiophene ring; R represents an alkyl group, an alkenyl group, an alkynyl group, an aromatic hydrocarbon group, an aromatic heterocyclic group, or a fluorine atom; L each independently represents a phenylene group or a thienylene group; Z each independently represents a group represented by Formula a-1; m each independently represents an integer of 0 to 4; when there are two or more L's, L's may be the same as or different from each other; when there are two or more Z's, Z's may be the same as or different from each other; x represents an integer of 1 to 3; y represents 0 or 1; z represents 0 or 1; and the symmetry of a ring-fused structure formed of the rings A to E is C₂, C₂ᵥ, or C₂ₕ.

In Formula A-2, the rings A to E each independently represent a benzene ring or a thiophene ring. It is preferable that 2 to 4 rings among the rings A to E are thiophene rings.

x represents an integer of 1 to 3. That is, the rings A to E have a ring-fused structure including 5 to 7 rings.

y represents 0 or 1, and is preferably 1.

z represents 0 or 1, and is preferably 0.

In Formula A-2, Lₘ-Z substitutes the ring E on a terminal of the fused polycyclic aromatic group constituted with the rings A to E. Furthermore, either or both of-Lₘ-Z and R substitute the ring A present on the other terminal. In the compound represented by Formula A-2, when y is 1, z is preferably 0, and when y is 0, z is preferably 1.

In Formula A-2, R represents an alkyl group, an alkenyl group, an alkynyl group, an aromatic hydrocarbon group, an aromatic heterocyclic group, or a fluorine atom. The alkyl group may be linear, branched, or cyclic, and is preferably linear. The alkyl group preferably has 1 to 20 carbon atoms, more preferably has 1 to 12 carbon atoms, and even more preferably 1 to 8 carbon atoms. The alkenyl group preferably has 2 to 20 carbon atoms, more preferably 2 to 12 carbon atoms, and even more preferably 2 to 8 carbon atoms. The alkynyl group preferably has 2 to 20 carbon atoms, more preferably has 2 to 12 carbon atoms, and even more preferably has 2 to 8 carbon atoms. The alkenyl group and the alkynyl group may be linear, branched, or cyclic, and are preferably linear. The aromatic hydrocarbon group preferably has 6 to 30 carbon atoms, more preferably has 6 to 20 carbon atoms, and even more preferably has 6 to 10 carbon atoms. The aromatic hydrocarbon group is particularly preferably a phenyl group. The aromatic heterocyclic group preferably has at least one heteroatom selected from the group consisting of a sulfur atom, an oxygen atom, a nitrogen atom, and a selenium atom, and more preferably has a heteroatom selected from the group consisting of a sulfur atom, a nitrogen atom, and an oxygen atom. The heterocyclic group may be monocyclic or polycyclic, and is preferably a 5-to 30-membere ring, more preferably 5-to 20-membered ring, and even more preferably a 5-to 10-membered ring.

Among these, R is preferably an alkyl group, and particularly preferably a linear alkyl group.

It is preferable tha, in the compound represented by Formula A-2, the rings A and E are thiophene rings and/or L is a thienylene ring and m is an integer of 1 to 4. That is, the group represented by Formula a-1 is preferably substituted with a thiophene ring. Furthermore, in the group represented by Formula a-1, p is preferably an integer of 1 to 6.

In Formula A-2, the symmetry of the ring-fused structure formed of the rings A to E is C₂, C₂ᵥ, or C₂ₕ. If the symmetry is C₂, C₂ᵥ, or C₂ₕ, a well-ordered crystal structure is easily obtained, and high mobility is easily exhibited.

Regarding the symmetry of a ring-fused structure, the description of “Molecular Symmetry and Theory of Groups” (Masao Nagazaki, Tokyo Kagaku Dojin) can be referred to.

Examples of the component A and the organic semiconductor compound of the present invention (compound represented by Formula A-2) will be shown below, but the present invention is not limited to the examples.

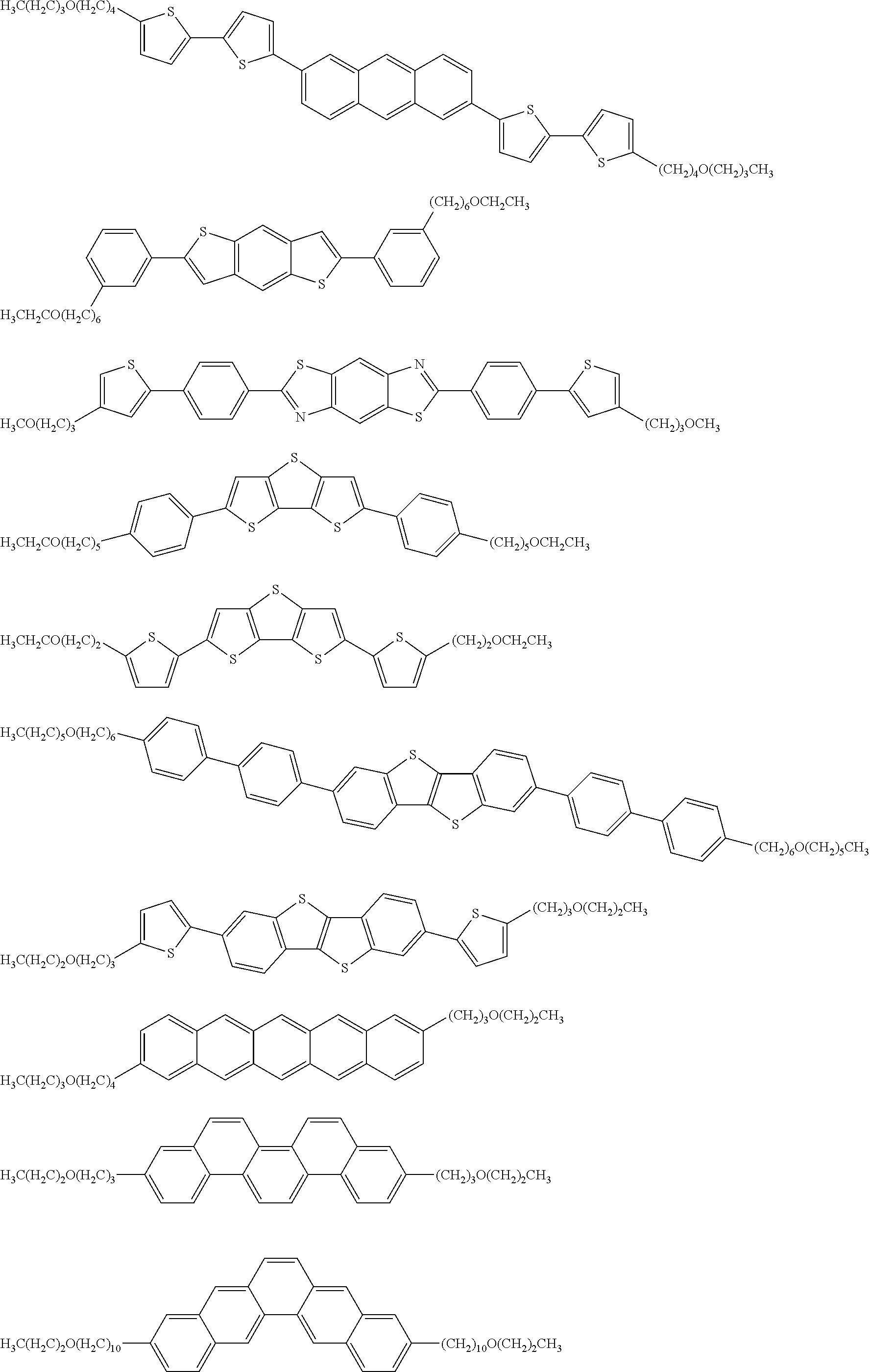

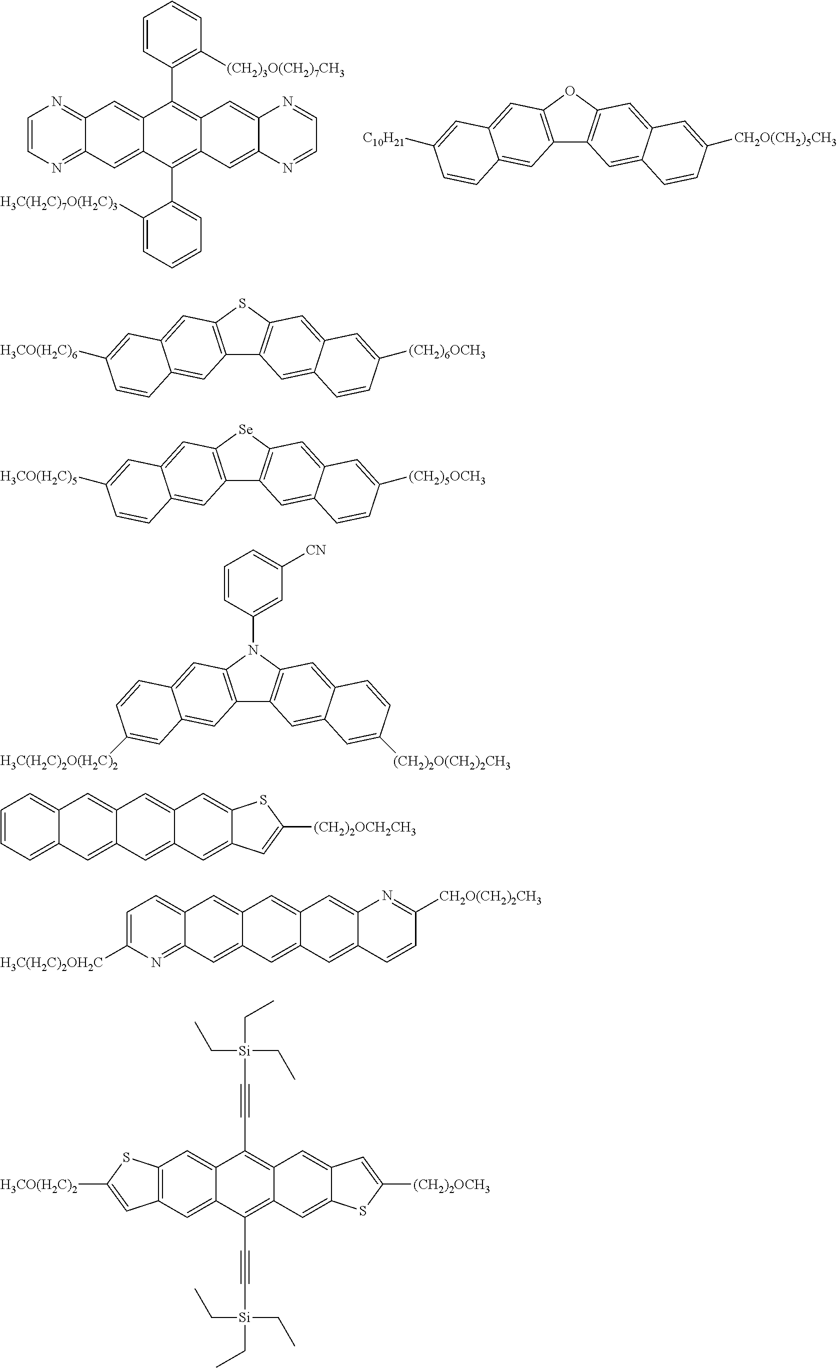

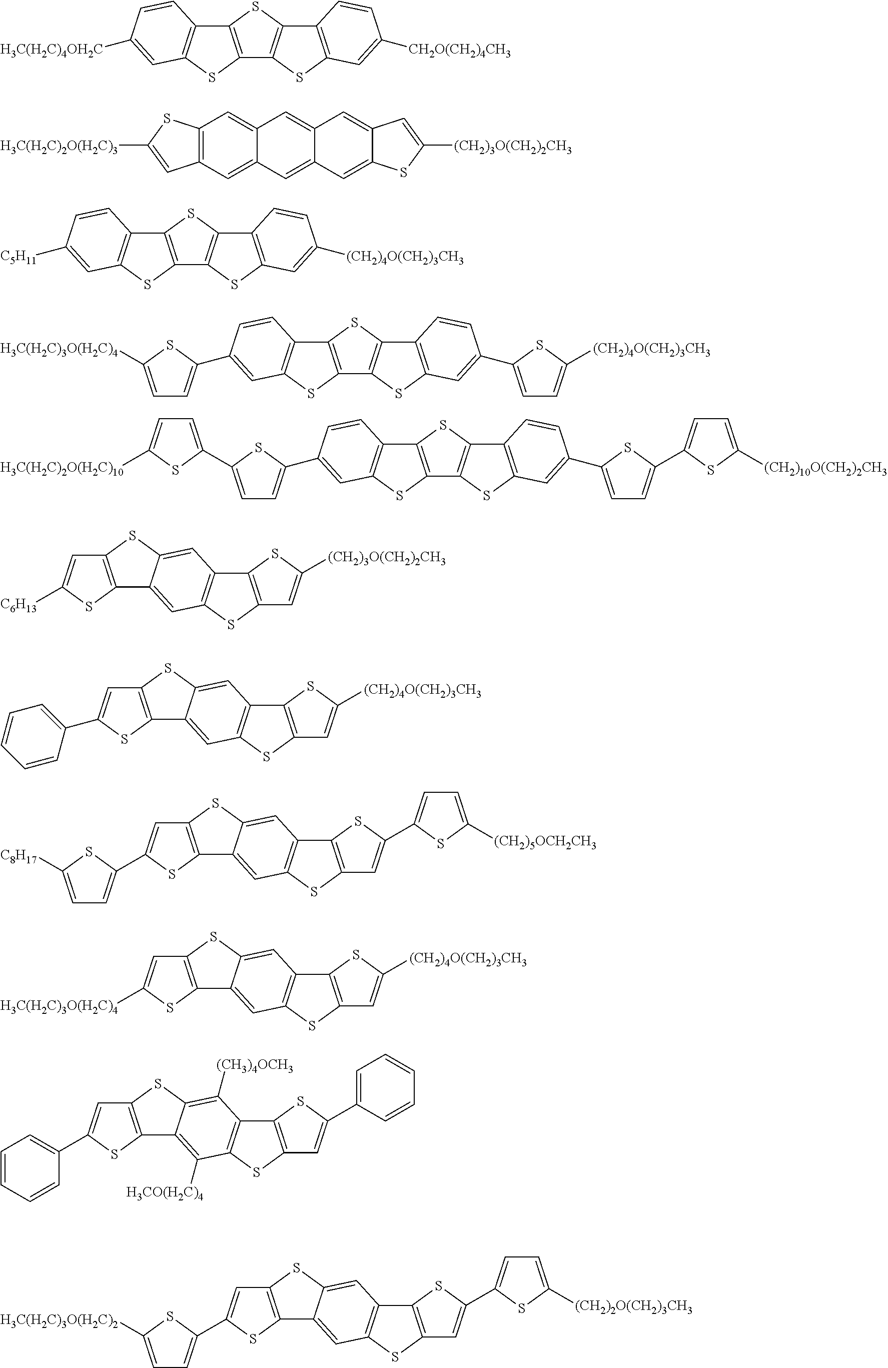

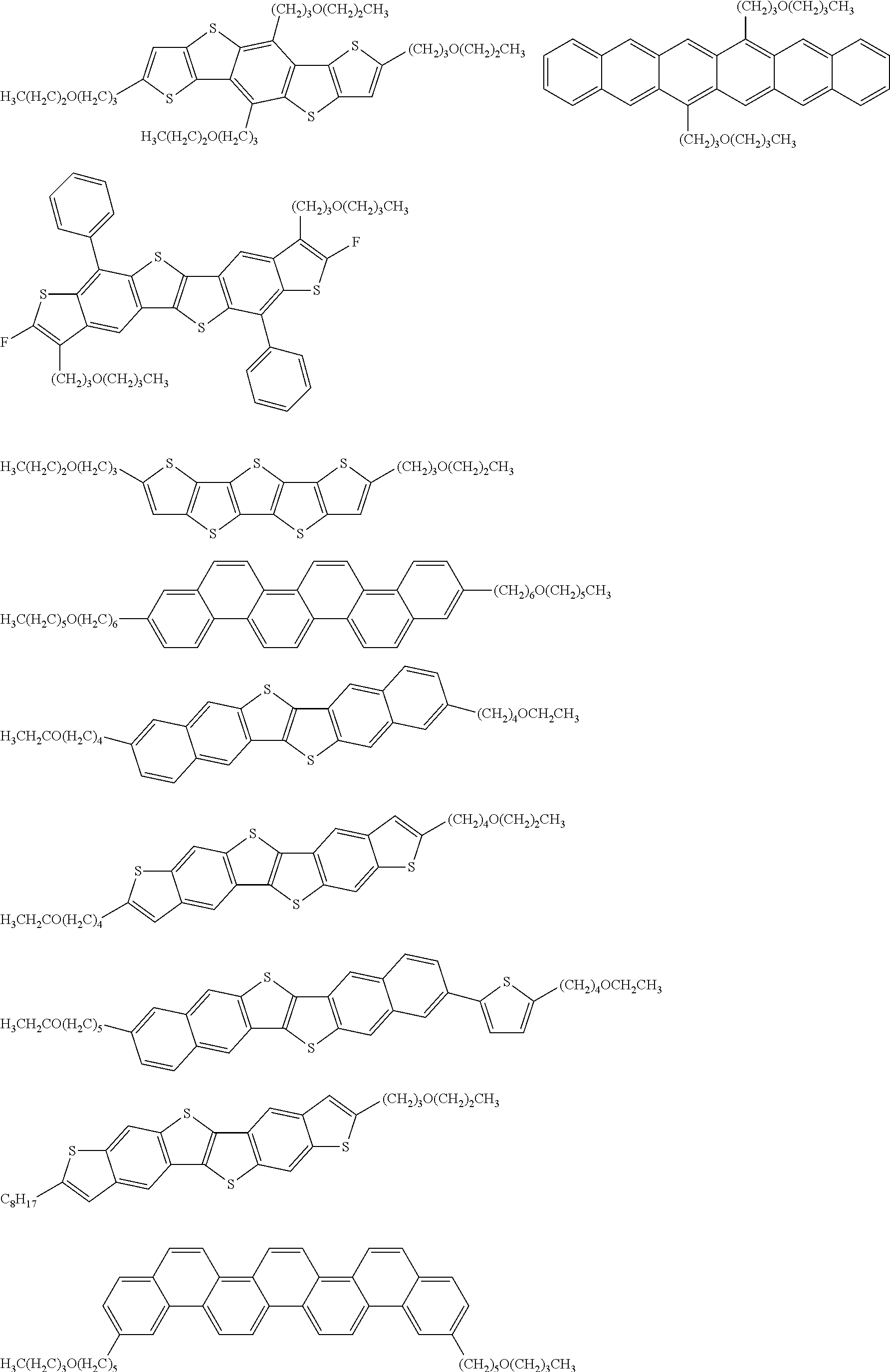

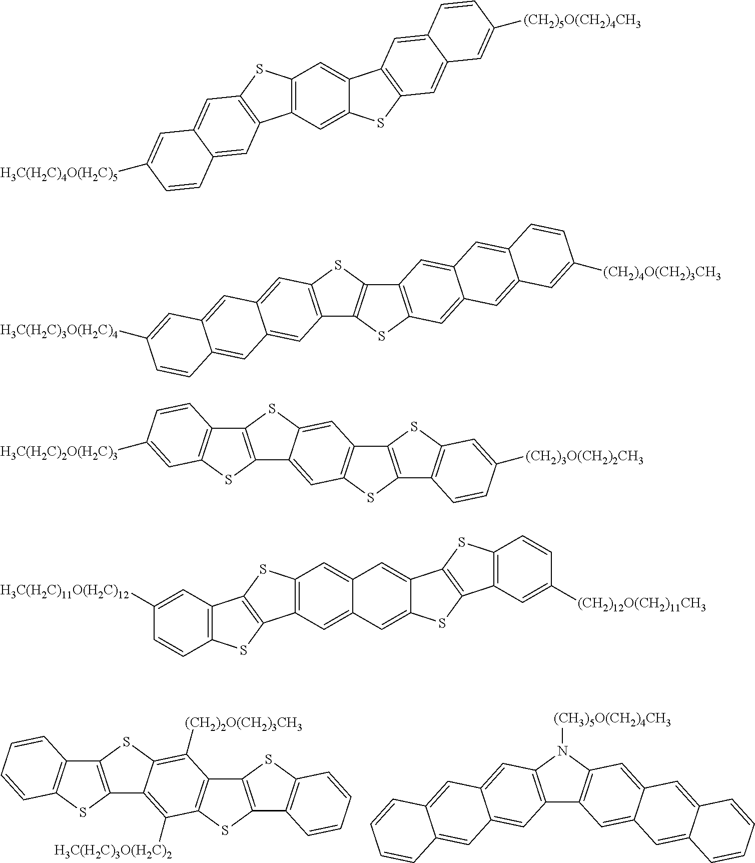

A molecular weight of the component A is not particularly limited, but is preferably equal to or less than 1,500, more preferably equal to or less than 1,000, and even more preferably equal to or less than 800. If the molecular weight is equal to or less than the aforementioned upper limit, the solubility of the component A in a solvent can be improved. In contrast, from the viewpoint of the qualitative stability of a thin film, the molecular weight is preferably equal to or greater than 400, more preferably equal to or greater than 450, and even more preferably equal to or greater than 500.

One kind of component A may be used singly, or two or more kinds thereof may be used in combination.

A method for manufacturing the component A is not particularly limietd, and the component A can be synthesized with reference to known methods. Specifically, it is possible to refer to JP2013-191821A, JP2009-246140A, JP2011-32268A, JP2009-54810A, JP2011-526588A, JP2012-510454A, JP2010-520241A, JP2010-6794A, JP2006-176491A, US2008/0142792A, WO2010/098372A, Adv. Mater. 2013, 25, 6392., Chem. Commun. 2014, 50, 5342., Appl. Phys. Express, 2013, 6, 076503., and Scientific Reports 2014, 4, 5048.

A content of the component A in the composition for forming an organic semiconductor film of the present invention is, with respect to a total amount of solid contents, preferably 30% to 100% by mass, more preferably 50% to 100% by mass, and even more preferably 70% to 100% by mass. In a case where the composition does not contain a binder polymer which will be described later, the aforementioned total content is preferably 90% to 100% by mass, and more preferably 95% to 100% by mass.

The content of the component A in the composition for forming an organic semiconductor film of the present invention is equal to or greater than 0.7% by mass and less than 15% by mass. If the content of the component A is less than 0.7% by mass, a concentration of the component A in the composition for forming an organic semiconductor film is low, and it is difficult to obtain an organic semiconductor film and an organic semiconductor element having high mobility and driving stability. In contrast, if the content of the component A is equal to or greater than 15% by mass, the concentration of the component A is high, and the preservation stability deteriorates.

The content of the component A in the composition for forming an organic semiconductor film is preferably 1.0% to 10% by mass, more preferably 1.25% to 10% by mass, and even more preferably 1.5% to 10% by mass.

Component B: solvent

The composition for forming an organic semiconductor film of the present invention contains a solvent as a component B, and a content of a non-halogen-based solvent is equal to or greater than 50% by mass and less than 100% by mass with respect to a total content of the component B. Herein, the “non-halogen-based solvent” is a solvent not having a halogen atom.

If the content of the non-halogen-based solvent is less than 50% by mass, an organic semiconductor film and an organic semiconductor element having excellent driving stability cannot be obtained.

The component B is not particularly limited as long as the component B dissolves the component A such that a solution having a desired concentration can be prepared or the component B can disperse the component A.

Examples of the non-halogen-based solvent include an aliphatic hydrocarbon-based organic solvent such as pentane, hexane, heptane, octane, decane, dodecane, isopentane, isohexane, isooctane, cyclohexane, methylcyclohexane, cyclopentane, or decalin; an aromatic hydrocarbon-based solvent such as benzene, toluene, o-xylene, m-xylene, p-xylene, ethylbenzene, mesitylene, tetralin, cyclohexylbenzene, diethylbenzene, or 1-methylnaphthalene; an ester-based solvent such as methyl formate, ethyl formate, propyl formate, methyl acetate, ethyl acetate, isopropyl acetate, n-propyl acetate, isobutyl acetaet, n-butyl acetate, amyl acetate, methyl propionate, or ethyl propionate, an alcohol-based solvent such as methanol, ethanol, propanol, butanol, pentanol, hexanol, cyclohexanol, a-terpineol, methyl cellosolve, ethyl cellosolve, or ethylene glycol, a ketone-based solvent such as acetone, methyl ethyl ketone, methyl isobutyl ketone, cyclohexanone, 2-hexanone, 2-heptanone, or 2-octanone; an alkylene glycol-based solvent such as diethylene glycol ethyl ether, diethylene glycol diethyl ether, propylene glycol monomethyl ehter, propylene glycol monoethyl ether, propylene glycol monopropyl ether, propylene glycol monobutyl ether, propylene glycol monomethyl ether acetate, diethylene glycol methyl ether acetate, diethylene glycol ethyl ether acetate, diethylene glycol propyl ether acetate, diethylene glycol isopropyl ether acetate, diethylene glycol butyl ether acetate, diethylene glycol-t-butyl ether acetate, triethylene glycol methyl ether acetate, triethylene glycol ethyl ether acetate, triethylene glycol propyl ether acetate, triethylene glycol isopropyl ether acetate, triethylene glycol butyl ether acetate, triethylene glycol-t-butyl ether acetate, dipropylene glycol dimethyl ether, or dipropylene glycol monobutyl ether; an ether-based solvent such as diethyl ether, dipropyl ether, diisopropyl ether, dibutyl ether, dihexyl ether, ethyl vinyl ether, butyl vinyl ether, anisole, butyl phenyl ether, pentyl phenyl ether, methoxytoluene, benzyl ethyl ether, diphenyl ether, dibenzyl ether, dioxane, furan, or tetrahydrofuran; an amide-imide-based solvent such as N,N-dimethylformamide, N,N-dimethylacetamide, 1-m ethyl-2-pyrrolidone, or 1-methyl-2-imidazolidinone; a sulfoxide-based solvent such as dimethyl sulfoxide; a nitrile-based solvent such as acetonitrile; or the like, but the non-halogen-based solvent is not particularly limited.

Examples of halogen-based solvents which may be used in combination with the above non-halogen-based solvents include dichloromethane, chloroform, tetrachloromethane, dichloroethane, trichloroethane, chlorobenzene, chlorotoluene, 1 ,2-dichlorobenzene, trichlorobenzene (1,2,4-trichlorobenzene or the like), and the like.

From the viewpoint of the stability of the composition for forming an organic semiconductor film and from the viewpoint of forming a uniform film, a boiling point of the component B under normal pressure is preferably equal to or higher than 100° C., more preferably equal to or higher than 150° C., even more preferably equal to or higher than 175° C., and particularly preferably equal to or higher than 200° C. From the viewpoint of drying the component B after the application of the composition for forming an organic semiconductor film, the boiling point of the component B is preferably equal to or lower than 300° C., more preferably equal to or lower than 250° C., and even more preferably equal to or lower than 220° C.

The non-halogen-based solvent contains an aromatic solvent preferably in an amount of equal to or greater than 50% by mass. If the non-halogen-based solvent contains the aromatic solvent in an amount of equal to or greater than 50% by mass, the solubility of the component A becomes excellent, and an organic semiconductor film or an organic semiconductor element having high driving stability is obtained.

The non-halogen-based solvent contains the aromatic solvent more preferably in an amount of equal to or greater than 70% by mass, and even more preferably in an amount of equal to or greater than 85% by mass. It is particularly preferable that the non-halogen-based solvent is totally composed of the aromatic solvent, that is, the aromatic solvent accounts for 100% by mass of the non-halogen-based solvent.

As the component B, a non-halogen-based aromatic solvent having a boiling point of equal to or higher than 100° C. is preferable. Specific examples thereof include toluene (boiling point: 111° C.), xylene (boiling point: 138° C. to 144° C.), anisole (boiling point: 154° C.), mesitylene (boiling point: 165° C.), diethyl benzene (boiling point: 180° C. to 182° C.), and tetralin (boiling point: 208° C.).

One kind of component B may be used singly, or two or more kinds thereof may be used in combination.

The component B should be appropriately added such that the content of the component A in the composition for forming an organic semiconductor film and an amount of total solid contents thereof which will be described later fall into a desired range.

Component C: binder polymer

The composition for forming an organic semiconductor film of the present invention preferably contains a binder polymer as a component C.

Furthermore, an organic semiconductor film and an organic semiconductor element of the present invention may be an organic semiconductor element having a layer containing the aforementioned organic semiconductor compound and a layer containing the binder polymer.

The type of binder polymer is not particularly limited, and known binder polymers can be used.

Examples of the binder polymer include an insulating polymer such as polystyrene, polycarbonate, polyarylate, polyester, polyamide, polyimide, polyurethane, polysiloxane, polysulfone, polymethyl methacrylate, polymethyl acrylate, cellulose, polyethylene, or polypropylene and a copolymer of these, a semiconductor polymer such as polysilane, polycarbazole, polyarylamine, polyfluorene, polythiophene, polypyrrole, polyaniline, polyparaphenylene vinylene, polyacene, or polyheteroacene and a copolyme of these, rubber, and thermoplastic elastomer.

Among these, as the binder polymer, a benzene ring-containing polymer compound (polymer having a benzene ring group-containing monomer unit) is preferable. A content of the benzene ring group-containing monomer unit is not particularly limited, but is preferably equal to or greater than 50 mol %, more preferably equal to or greater than 70 mol %, and even more preferably equal to or greater than 90 mol % with respect to all of the monomer units. An upper limit of the content is not particularly limited and is, for example, 100 mol %.

Examples of the aforementioned binder polymer include polystyrene, poly(α-methyl styrene), polyvinyl cinnamate, poly(4-vinylphenyl), poly(4-methyl styrene), poly[bis(4-phenyl)(2,4,6-trimethylphenyl)amine], poly[2,6-(4,4-bis(2-ethylhexyl)-4H cyclopenta[2,1-b;3,4-b′] dithiophene)-alt-4,7-(2,1,3-benzothiadiazole)], and the like. Among these, poly(α-methyl styrene) is particularly preferable.

A weight-average molecular weight of the binder polymer is not particularly limited, but is preferably 1,000 to 2,000,000, more preferably 3,000 to 1,000,000, and even more preferably 5,000 to 600,000.

It is preferable that, in the component B, the solubility of the binder polymer is higher than the solubility of the component A. If this aspect is adopted, the mobility and heat stability of the obtained organic semiconductor are further improved.

A content of the binder polymer in the composition for forming an organic semiconductor film of the present invention is, with respect to 100 parts by mass of the content of the component A, preferably 1 to 10,000 parts by mass, more preferably 10 to 1,000 parts by mass, even more preferably 25 to 400 parts by mass, and most preferably 50 to 200 parts by mass. If the content is within the above range, the mobility and film uniformity of the obtained organic semiconductor are further improved.

<Other Components>

The composition for forming an organic semiconductor film of the present invention may contain other components in addition to the components A to C.

As other components, known additives and the like can be used.

A concentration of total solid contents in the composition for forming an organic semiconductor film of the present invention is preferably equal to or higher than 1.5% by mass. Herein, the “solid contents” is an amount of components excluding a volatile component such as a solvent. That is, the concentration of total solid contents including the components A and C is preferably equal to or higher than 1.5% by mass. It is preferable that the concentration of solid contents is equal to or higher than 1.5% by mass, because then excellent film formability is exhibited in various printing methods.

The concentration of total solid contents in the composition for forming an organic semiconductor film is more preferably equal to or higher than 2% by mass, and even more preferably equal to or higher than 3% by mass. An upper limit of the concentration is not limited. From the viewpoint of the solubility of the component A or the like, the upper limit is preferably equal to or lower than 20% by mass, more preferably equal to or lower than 15% by mass, and even more preferably equal to or lower than 10% by mass. If the upper limit is within the above range, the preservation stability and film formability become excellent, and the mobility of the obtained organic semiconductor is further improved.

The composition for forming an organic semiconductor film of the present invention is suitable for ink jet printing and/or flexographic printing.

A viscosity of the composition for forming an organic semiconductor film of the present invention is not particularly limited. From the viewpoint of further improving suitability for various printing methods, particularly, suitability for ink jet printing and flexographic printing, the viscosity is preferably 3 to 100 mPa·s, more preferably 5 to 50 mPa·s, even more preferably 5 to 40 mPa·s, and particularly preferably 9 to 40 mPa·s. The viscosity in the present invention is a viscosity at 25° C.

As a method for measuring the viscosity, a method based on JIS Z8803 is preferable.

A method for manufacturing the composition for forming an organic semiconductor film of the present invention is not particularly limited, and known methods can be adopted. For example, by adding a predetermined amount of component A to the component B and appropriately stirring the mixture, a desired composition can be obtained. In a case where the component C is used, the composition can be suitably prepared by simultaneously or sequentially adding the components A and C.

(Organic Semiconductor Film and Organic Semiconductor Element)

The organic semiconductor film of the present invention is manufactured using the composition for forming an organic semiconductor film of the present invention, and the organic semiconductor element of the present invention is manufactured using the composition for forming an organic semiconductor film of the present invention.

A method for manufacturing the organic semiconductor film or the organic semiconductor element by using the composition for forming an organic semiconductor film of the present invention is not particularly limited, and known methods can be adopted. Examples thereof include a method for manufacturing an organic semiconductor film or an organic semiconductor element by applying the composition onto a predetermined substrate and performing a drying treatment if necessary.

A method for applying the composition onto a substrate is not particularly limited, and known methods can be adopted. Examples thereof include an ink jet printing method, a flexographic printing method, a bar coating method, a spin coating method, a knife coating method, a doctor blade method, a drop casting method, and the like. Among these, an ink jet printing method, a flexographic printing method, a spin coating method, and a drop casting method are preferable, and an ink jet printing method and a flexographic printing method are particularly preferable.

As the flexographic printing method, an aspect in which a photosensitive resin plate is used as a flexographic printing plate is suitably exemplified. By printing the composition onto a substrate according to the aspect, a pattern can be easily formed.

Among these, the method for manufacturing an organic semiconductor film of the present invention and the method for manufacturing an organic semiconductor element of the present invention more preferably include an application step of applying the composition for forming an organic semiconductor film of the present invention onto a substrate, and a removing step of removing a solvent from the applied composition.

The drying treatment in the removing step is a treatment performed if necessary, and the optimal treatment conditions are appropriately selected according to the type of the specific compound and the solvent used. In view of further improving the mobility and heat stability of the obtained organic semiconductor and improving productivity, a heating temperature is preferably 30° C. to 150° C. and more preferably 40° C. to 100° C., and a heating time is preferably 1 to 300 minutes and more preferably 10 to 120 minutes.

A film thickenss of the formed organic semiconductor film of the present invention is not particularly limited. From the viewpoint of the mobility and heat stability of the obtained organic semiconductor, the film thickness is preferably 5 to 500 nm and more preferably 20 to 200 nm.

The organic semiconductor film of the present invention can be suitably used in an organic semiconductor element, and can be particularly suitably used in an organic transistor (organic thin film transistor).

The organic semiconductor film of the present invention is suitably prepared using the composition for forming an organic semiconductor film of the present invention.

<Organic Semiconductor Element>

The organic semiconductor element is not particularly limited, but is preferably an organic semiconductor element having 2 to 5 terminals, and even more preferably an organic semiconductor element having 2 or 3 terminals.

Furthermore, the organic semiconductor element is preferably an element which does not use a photoelectric function.

In addition, the organic semiconductor element of the present invention is preferably a non-light emitting organic semiconductor element.

Examples of the 2-terminal element include a rectifier diode, a constant voltage diode, a PIN diode, a Schottky barrier diode, a surge protection diode, a diac, a varistor, a tunnel diode, and the like.

Examples of the 3-terminal element include a bipolar transistor, a Darlington transistor, a field effect transistor, insulated gate bipolar transistor, a uni-junction transistor, a static induction transistor, a gate turn-off thyristor, a triac, a static induction thyristor, and the like.

Among these, a rectifier diode and transistors are preferable, and a field effect transistor is more preferable. Examples of the field effect transistor preferably include an organic thin film transistor.

An aspect of the organic thin film transistor of the present invention will be described with reference to a drawing.

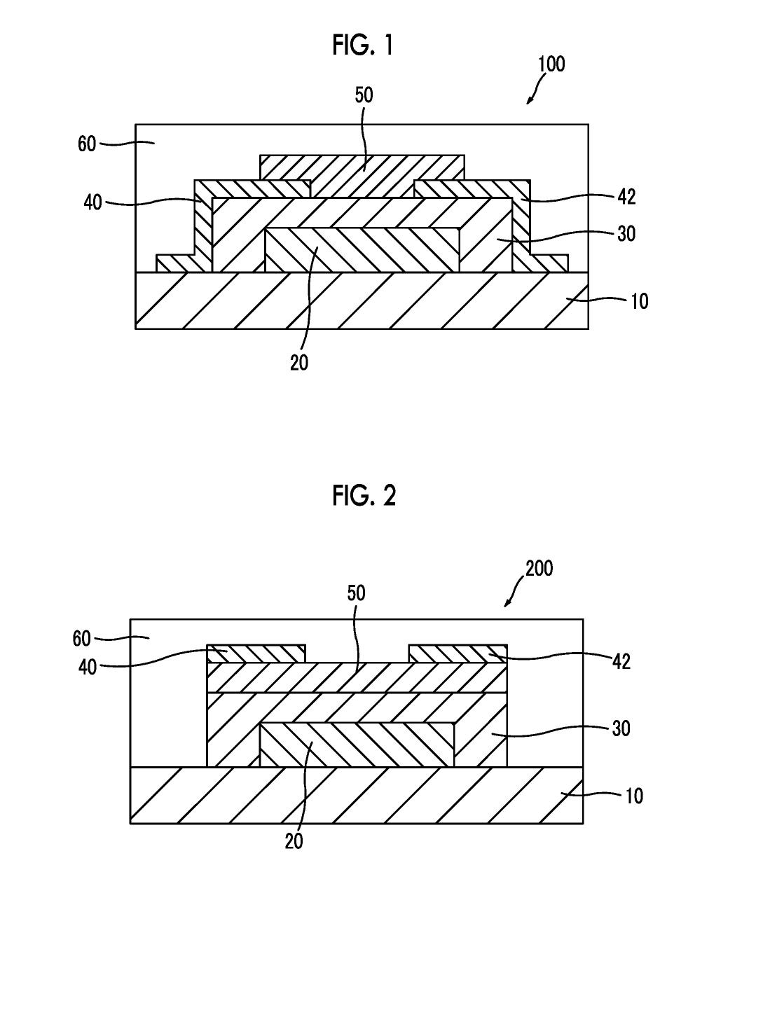

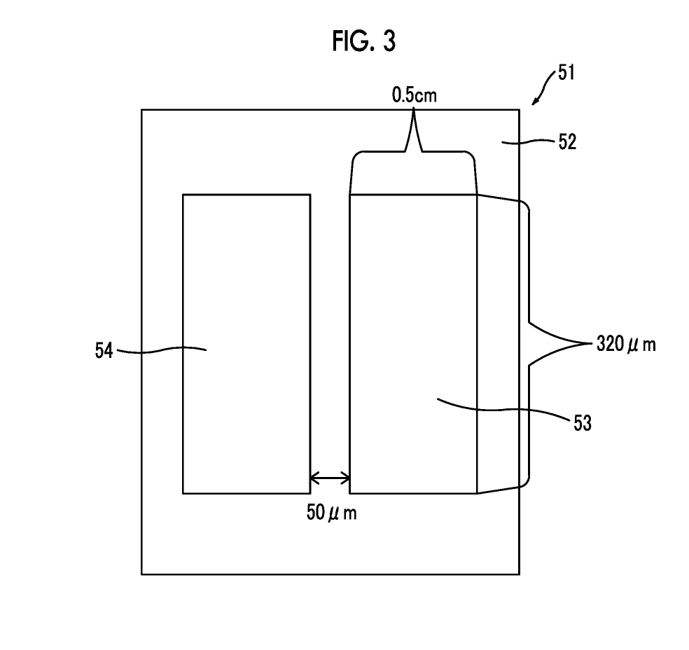

FIG. 1 is a schematic cross-sectional view of an aspect of an organic semiconductor element (organic thin film transistor (TFT)) of the present invention.

In FIG. 1, an organic thin film transistor 100 includes a substrate 10, a gate electrode 20 disposed on the substrate 10, a gate insulating film 30 covering the gate electrode 20, a source electrode 40 and a drain electrode 42 which contact a surface of the gate insulating film 30 that is on the side opposite to the gate electrode 20 side, an organic semiconductor film 50 covering a surface of the gate insulating film 30 between the source electrode 40 and the drain electrode 42, and a sealing layer 60 covering each member. The organic thin film transistor 100 is a bottom gate-bottom contact type organic thin film transistor.

In FIG. 1, the organic semiconductor film 50 corresponds to a film formed of the composition described above.

Hereinafter, the substrate, the gate electrode, the gate insulating film, the source electrode, the drain electrode, the organic semiconductor film, the sealing layer, and methods for forming each of these will be specifically described.

[Substrate]

The substrate plays a role of supporting the gate electrode, the source electrode, the drain electrode, and the like which will be described later.

The type of the substrate is not particularly limited, and examples thereof include a plastic substrate, a glass substrate, a ceramic substrate, and the like. Among these, from the viewpoint of applicability to each device and costs, a glass substrate or a plastic substrate is preferable.

Examples of materials of the plastic substrate include a thermosetting resin (for example, an epoxy resin, a phenol resin, a polyimide resin, or a polyester resin (for example, polyethylene terephthalate (PET) or polyethylene naphthalate (PEN)) and a thermoplastic resin (for example, a phenoxy resin, a polyethersulfone, polysulfone, or polyphenylene sulfone).

Examples of materials of the ceramic substrate include alumina, aluminum nitride, zirconia, silicon, silicon nitride, silicon carbide, and the like.

Examples of materials of the glass substrate include soda lime glass, potash glass, borosilicate glass, quartz glass, aluminosilicate glass, lead glass, and the like.

[Gate Electrode, Source Electrode, and Drain Electrode]

Examples of materials of the gate electrode, the source electrode, and the drain electrode include a metal such as gold (Au), silver, aluminum (Al), copper, chromium, nickel, cobalt, titanium, platinum, tantalum, magnesium, calcium, barium, or sodium; a conductive oxide such as InO₂, SnO₂, or indium tin oxide (ITO); a conductive polymer such as polyaniline, polypyrrole, polythiophene, polyacetylene, or polydiacetylene; a semiconductor such as silicon, germanium, or gallium arsenide; a carbon material such as fullerene, carbon nanotubes, or graphite; and the like. Among these, a metal is preferable, and silver and aluminum are more preferable.

A thickness of each of the gate electrode, the source electrode, and the drain electrode is not particularly limited, but is preferably 20 to 200 nm.

A method for forming the gate electrode, the source electrode, and the drain electrode is not particularly limited, but examples thereof include a method of vacuum vapor-depositing or sputtering an electrode material onto a substrate, a method of coating a substrate with a composition for forming an electrode, a method of printing a composition for forming an electrode onto a substrate, and the like. Furthermore, in a case where the electrode is patterned, examples of the patterning method include a photolithography method; a printing method such as ink jet printing, screen printing, offset printing, or relief printing; a mask vapor deposition method; and the like.

[Gate Insulating Film]

Examples of materials of the gate insulating film include a polymer such as polymethyl methacrylate, polystyrene, polyvinylphenol, polyimide, polycarbonate, polyester, polyvinyl alcohol, polyvinyl acetate, polyurethane, polysulfone, polybenzoxazole, polysilsesquioxane, an epoxy resin, or a phenol resin; an oxide such as silicon dioxide, aluminum oxide, or titanium oxide; a nitride such as silicon nitride; and the like. Among these materials, in view of the compatibility with the organic semiconductor film, a polymer is preferable.

In a case where a polymer is used as the material of the gate insulating film, it is preferable to use a cross-linking agent (for example, melamine) in combination. If the cross-linking agent is used in combination, the polymer is cross-linked, and durability of the formed gate insulating film is improved.

A film thickness of the gate insulating film is not particularly limited, but is preferably 100 to 1,000 nm.

A method for forming the gate insulating film is not particularly limited, but examples thereof include a method of coating a substrate, on which the gate electrode is formed, with a composition for forming a gate insulating film, a method of vapor-depositing or sputtering the material of the gate insulating film onto a substrate on which the gate electrode is formed, and the like. A method for coating the aforementioned substrate with the composition for forming a gate insulating film is not particularly limited, and it is possible to use a known method (a bar coating method, a spin coating method, a knife coating method, or a doctor blade method).

In a case where the gate insulating film is formed by coating the substrate with the composition for forming a gate insulating film, for the purpose of removing the solvent, causing cross-linking, or the like, the composition may be heated (baked) after coating.

[Binder Polymer Layer]

The organic semiconductor element of the present invention preferably has the aforementioned binder polymer layer between the aforementioned organic semiconductor layer and the insulating film, and more preferably has the polymer layer between the aforementioned organic semiconductor layer and the gate insulating film. A film thickness of the binder polymer layer is not particularly limited, but is preferably 20 to 500 nm. The binder polymer layer should be a layer containing the aforementioned polymer, and is preferably a layer composed of the aforementioned binder polymer.

A method for forming the binder polymer layer is not particularly limited, and known methods (a bar coating method, a spin coating method, a knife coating method, a doctor blade method, and an ink jet method) can be used.

In a case where the binder polymer layer is formed by performing coating by using a composition for forming a binder polymer layer, for the purpose of removing a solvent or causing cross-linking, or the like, the composition may be heated (baked) after coating.

[Sealing Layer]

From the viewpoint of durability, the organic semiconductor element of the present invention preferably includes a sealing layer as an outermost layer. In the sealing layer, a known sealant can be used.

A thickness of the sealing layer is not particularly limited, but is preferably 0.2 to 10 μm.

A method for forming the sealing layer is not particularly limited, but examples thereof include a method of coating a substrate, on which the gate electrode, the gate insulating film, the source electrode, the drain electrode, and the organic semiconductor film are formed, with a composition for forming a sealing layer, and the like. Specific examples of the method of coating the substrate with the composition for forming a sealing layer are the same as the examples of the method of coating the substrate with the composition for forming a gate insulating film. In a case where the organic semiconductor film is formed by coating the substrate with the composition for forming a sealing layer, for the purpose of removing the solvent, causing cross-linking, or the like, the composition may be heated (baked) after coating.

FIG. 2 is a schematic cross-sectional view of another aspect of the organic semiconductor element (organic thin film transistor) of the present invention.

In FIG. 2, an organic thin film transistor 200 includes the substrate 10, the gate electrode 20 disposed on the substrate 10, the gate insulating film 30 covering the gate electrode 20, the organic semiconductor film 50 disposed on the gate insulating film 30, the source electrode 40 and the drain electrode 42 disposed on the organic semiconductor film 50, and the sealing layer 60 covering each member. Herein, the source electrode 40 and the drain electrode 42 are formed using the aforementioned composition of the present invention. The organic thin film transistor 200 is a top contact-type organic thin film transistor.

The substrate, the gate electrode, the gate insulating film, the source electrode, the drain electrode, the organic semiconductor film, and the sealing layer are as described above.

In FIGS. 1 and 2, the aspects of the bottom gate-bottom contact type organic thin film transistor and the bottom gate-top contact type organic thin film transistor were specifically described. However, the organic semiconductor element of the present invention can also be suitably used in a top gate-bottom contact type organic thin film transistor and a top gate-top contact type organic thin film transistor.

The aforementioned organic thin film transistor can be suitably used in electronic paper, a display device, and the like.

### EXAMPLES

Hereinafter, the present invention will be more specifically described based on examples. The materials and the amount thereof used, the proportion of the materials, the content and procedure of treatments, and the like described in the following examples can be appropriately changed within a scope that does not depart from the gist of the present invention. Accordingly, the scope of the present invention is not limited to the following specific examples. Herein, unless otherwise specified, “part” and “%” are based on mass.

(Organic Semiconductor)

The structures of compounds 1 to 19 and comparative compounds 1 to 8 used in organic semiconductor layers will be shown below.

The compound 1 was synthesized with reference to the method described in JP2013-191821A.

The compound 2 was synthesized with reference to the method described in JP2009-246140A.

The compounds 3 to 5 were synthesized with reference to the method described in JP2011-32268A.

The compounds 6 to 10 were synthesized with reference to the methods described in JP2009-54810A, JP2011-526588A, and JP2012-510454A.

The compound 11 was synthesized with reference to the method described in JP2010-520241A.

The compound 12 was synthesized with reference to the method described in Adv. Mater. 2013, 25, 6392.

The compound 13 was synthesized with reference to the method described in Chem. Commun. 2014, 50, 5342.

The compound 14 was synthesized with reference to the method described in US2008/0142792A.

The compound 15 was synthesized with reference to the method described in WO2010/098372A.

The compound 16 was synthesized with reference to the method described in Appl. Phys. Express 2013, 6, 076503.

The compound 17 was synthesized with reference to the method described in Scientific Reports 2014, 4, 5048.

The compound 18 was synthesized with reference to the method described in JP2010-6794A.

The compound 19 was synthesized with reference to the method described in JP2006-176491A.

The comparative compounds 1 and 2 are examples compounds 27 and 56 of JP2009-267132A respectively.

The comparative compounds 3 and 4 are compounds used in Examples 1 and 2 of JP2012-510454A.

The comparative compounds 5 and 6 are compounds 41 and 7 described in JP2011-32268A.

The comparative compound 7 is a compound (12) described in WO2010/098372A.

The comparative compound 8 was synthesized with reference to the methods described in JP2009-54810A and JP2011-526588A.

Through high-performance liquid chromatography (manufactured by TOSOH CORPORATION, TSKgel ODS-100Z), it was confirmed that all of the compounds had a purity (area ratio for absorption intensity at 254 nm) of equal to or higher than 99.8%. The structures of the compounds were identified by ¹H-NMR.

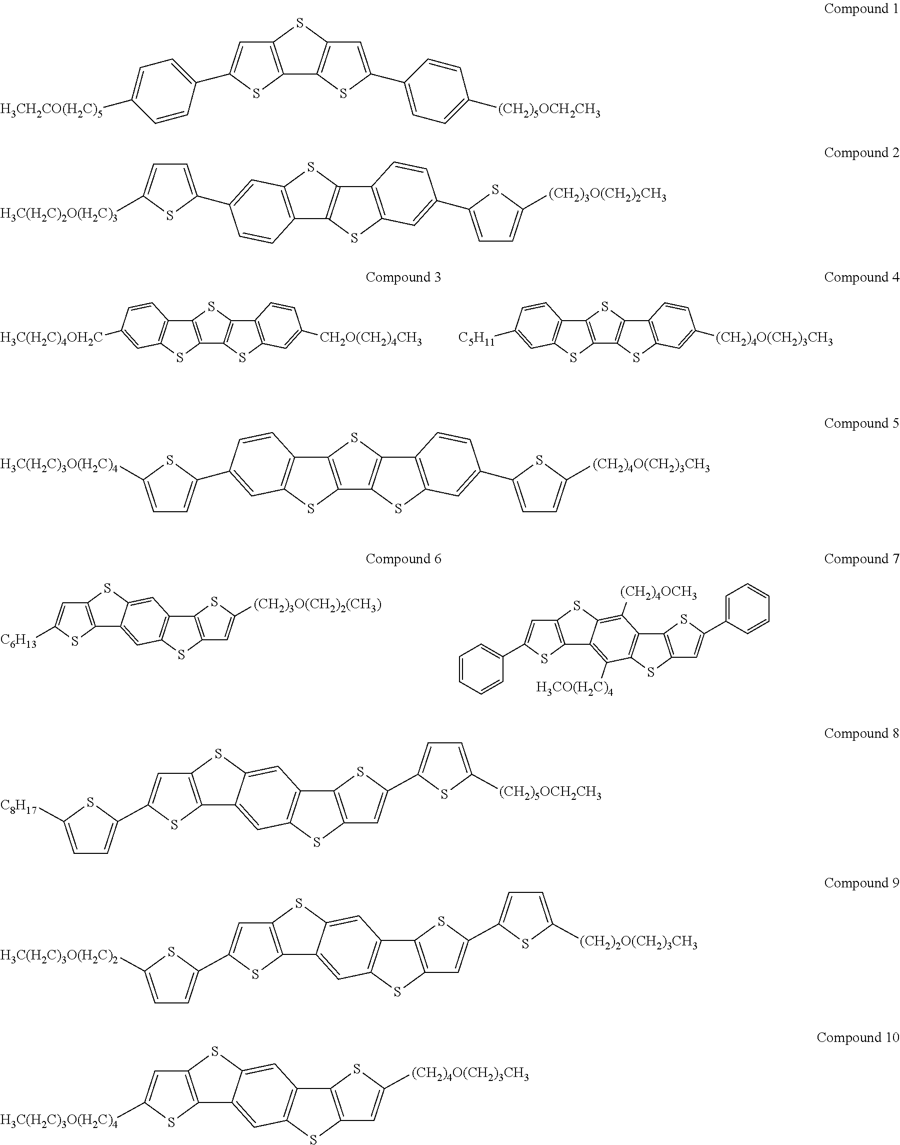

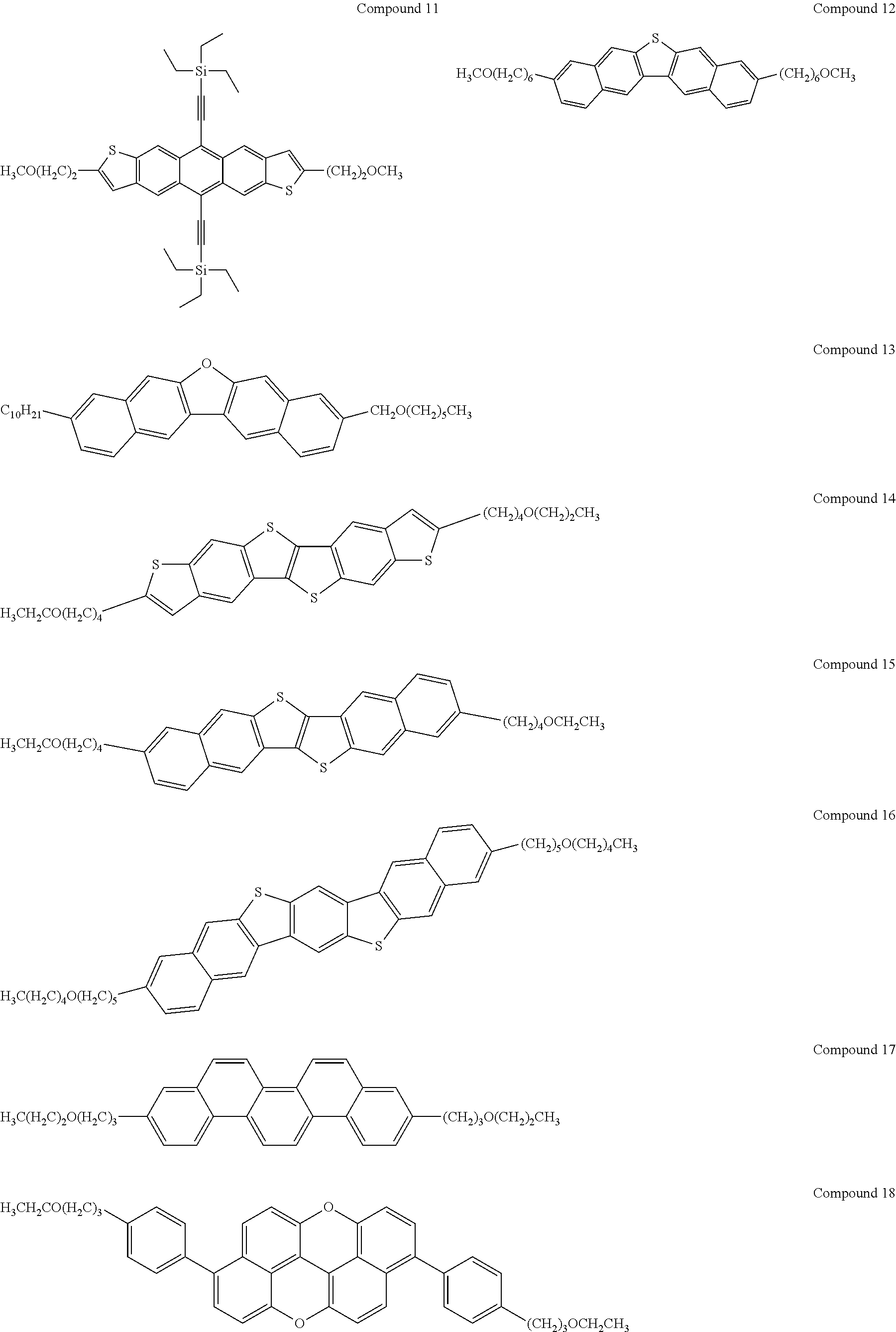

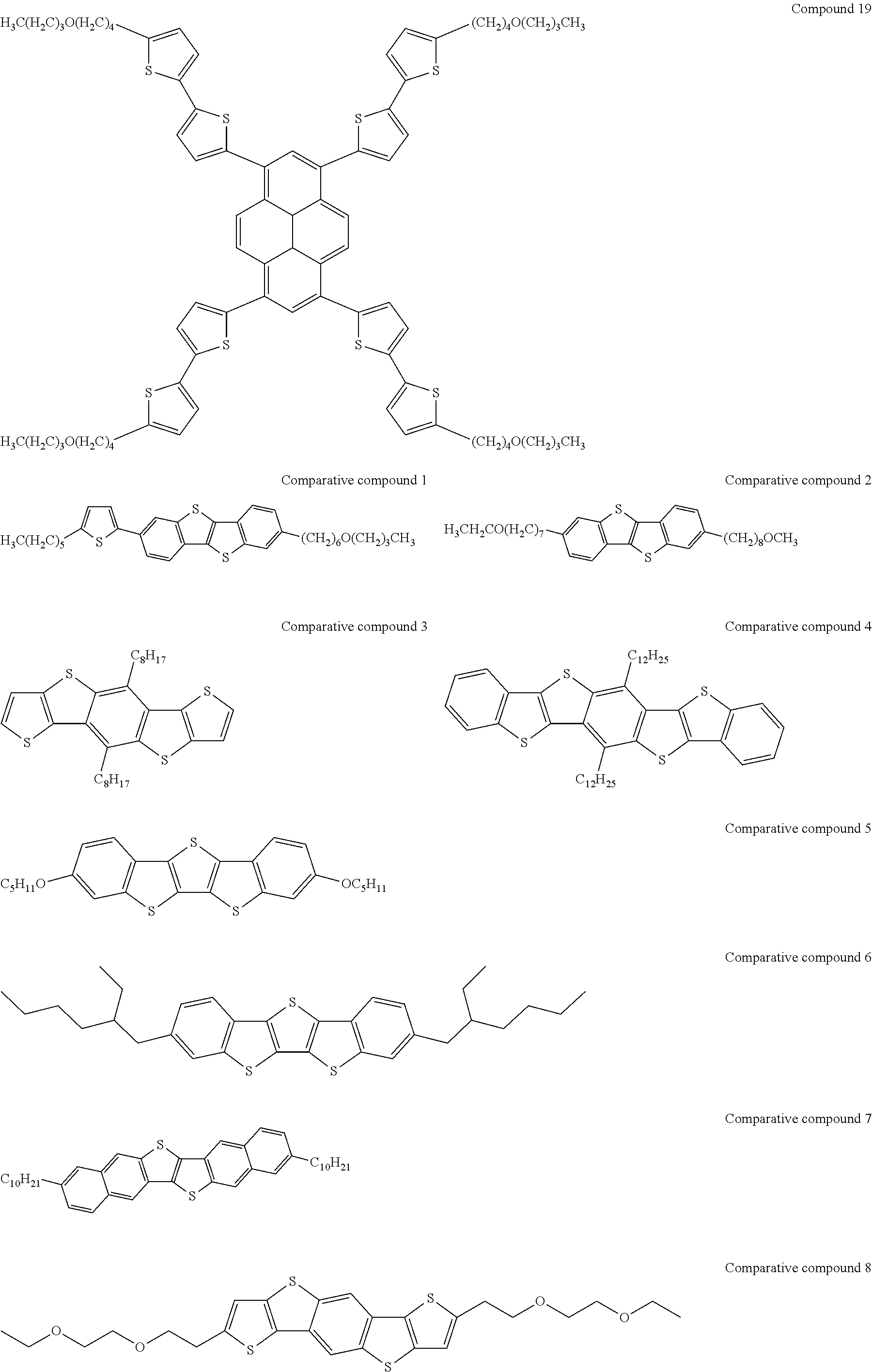

(Solvent)

The solvents used in examples and comparative examples will be shown below.

Tetralin: boiling point 208° C., manufactured by Sigma-Aldrich Co. LLC.

Mesitylene: boiling point 165° C., manufactured by Sigma-Aldrich Co. LLC.

Cyclohexanone: boiling point 156° C., manufactured by Sigma-Aldrich Co. LLC.

Diethylbenzene (isomer mixture): boiling point 180° C. to 182° C., manufactured by TOKYO CHEMICAL INDUSTRY CO., LTD.

Anisole: boiling point 154° C., manufactured by Sigma-Aldrich Co. LLC.

N-methylpyrrolidone: boiling point 202° C., manufactured by Sigma-Aldrich Co. LLC.

Chlorobenzene: boiling point 131° C., manufactured by Sigma-Aldrich Co. LLC.

Chloroform: boiling point 61° C., manufactured by Sigma-Aldrich Co. LLC.

(Binder Polymer)

The binder polymers used in examples and comparative examples will be shown below.

PαMS: poly-α-methylsytrene, weight-average molecular weight 437,000, manufactured by Sigma-Aldrich Co. LLC.

PTAA: poly[bis(4-phenyl)(2,4,6-trimethylphenyl)amine], number-average molecular weight 7,000 to 10,000, manufactured by Sigma-Aldrich Co. LLC.

PCPDTBT: poly[2,6-(4,4-bis(2-ethylhexyl)-4H cyclopenta[2,1-b ;3 ,4-b′] dithiophene)-alt-4,7-(2,1,3 -benzothiadiazole)], weight-average molecular weight 7,000 to 20,000, manufactured by Sigma-Aldrich Co. LLC.

<Preparation of Composition for Forming Organic Semiconductor Film>

The organic semiconductor (compound)/binder polymer/solvent described in Table 1 were weighed out in a glass vial at a concentration described in Table 1 and stirred and mixed together for 10 minutes by using MIX ROTOR (manufactured by AS ONE Corporation). The mixture was filtered through a 0.5 μm membrane filter, thereby obtaining a coating solution for forming an organic semiconductor film. The mark “-” in the column of binder polymer in the table means that the binder polymer was not added.

The concentration of the organic semiconductor and the binder polymer is a concentration (% by mass) with respect to a total amount of the composition for forming an organic semiconductor film.

<Preparation of TFT Element>

Onto a glass substrate (EAGLE XG: manufactured by Corning Incorporated), A1 to be a gate electrode was vapor-deposited (thickness: 50 nm). The AL was spin-coated with a composition for forming a gate insulatnig film (PGMEA (propylene glycol monomethyl ether acetate) solution (concentration of solid contents: 2% by mass) of polyvinylphenol/melamine =1 part by mass/1 part by mass (w/w)), followed by baking for 60 minutes at 150° C., thereby forming a gate insulating film having a film thickness of 400 nm. On the gate insulating film, by using a silver ink (H-1, manufactured by Mitsuibishi Materials Corporation) and an ink jet device DMP-2831 (manufactured by FUJIFILM Dimatix, Inc.), patterns of a source electrode and a drain electrode (channel length: 40 μm, channel width: 200 μm) were drawn. The substrate was then sintered by being baked for 30 minutes at 180° C. in an oven such that a source electrode and a drain electrode were formed, thereby obtaining an element substrate for TFT characteristic evaluation.

The element substrate for TFT characteristic evaluation was spin-coated with each composition for forming an organic semiconductor film (for 10 seconds at 500 rpm and then for 30 seconds at 1,000 rpm) and then dried for 10 minutes at 100° C. on a hot plate such that an organic semiconductor layer was formed, thereby obtaining a bottom gate-bottom contact type organic TFT element.

Furthermore, the composition for forming an organic semiconductor film was applied to the substrate by ink jet printing. Specifically, by using DPP 2831 (manufactured by FUJIFILM Dimatix, Inc.) as an ink jet device and a 10 pL head, a solid film was formed at a jetting frequency of 2 Hz and a dot pitch of 20 μm. Then, the film was dried for 1 hour at 70° C. such that an organic semiconductor layer was formed, thereby obtaining a bottom gate-bottom contact type organic TFT element.

In addition, the composition for forming an organic semiconductor film was applied to the substrate by flexographic printing. Specifically, as a printing device, a flexographic printability tester F1 (manufactured by IGT Testing Systems K.K.) was used, and as a flexographic resin plate, a plate-like photosensitive resin AFP DSH 1.70% (manufactured by Asahi Kasei Corporation.)/solid image was used. Printing was performed at a transport rate of 0.4 m/sec with applying a pressure of 60 N between the plate and the substrate, and then the substrate was dried as it was for 2 hours at room temperature of equal to or lower than 40° C. such that an organic semiconductor layer was formed, thereby obtaining a bottom gate-bottom contact type organic TFT element.

<Characteristic Evaluation>

By using a semiconductor characteristic evaluation device B2900A (manufactured by Agilent Technologies), the performance of the elements was evaluated as below in the atmosphere.

(a) Carrier Mobility

A voltage of −60 V was appilied between the source electrode and the drain electrode of each of the organic TFT elements, a gate voltage was varied within a range of +10 V to −60 V, and a carrier moblity μ was calcuated using the following equation showing a drain current I_{d}.

I_{d}=(w/2 L)μCᵢ(V_{g}−Vₜₕ)²

In the equation, L represents a gate length, W represents a gate width, Cᵢ represents a capacity of the insulating layer per unit area, V_{g} represents a gate voltage, and Vₜₕ represents a threshold voltage.

The higher the carrier mobility t, the more preferable. For practical use, the carrier mobility is preferably equal to or greater than 1×10⁻² cm²/Vs, and more preferably equal to or greater than 1×10⁻¹ cm²/Vs.

(b) Threshold Voltage Shift after Repeated Driving (Threshold Voltage Shift)

Between the source electrode and the drain electrode of each of the organic TFT elements, a voltage of −60 V was applied, and the element was repeatedly driven 500 times by varying the gate voltage within a range of +10 V to −60 V. In this way, the element was measured in the same manner as in (a), and a difference between a threshold voltage V_{before} before the repeated driving and a threshold voltage V_{after} after the repeated driving (|V_{after}-V_{before}) was evaluated into 5 levels as below. The smaller the difference, the higher the stability of the element against repeated driving. Therefore, the smaller the difference, the more preferable. For practical use, the difference is preferably S or A, and more preferably S.

S:|V_{after}−V_{before}|≦2V

A:2V<|V_{after}−V_{before}|≦3V

B:3V<|V_{after}−V_{before}|≦6V

C:6V<|V_{after}−V_{before}|≦9V

D:|V_{after}−V_{before}|>9V

(c) Mobility Retention Rate in Case where Coating Solution having Undergone Cold Preservation (Mobility Retention Rate)

Organic TFT elements were prepared in the same manner as described above, except that a composition for forming an organic semiconductor film was used which was cold-preserved for 7 days at 0° C. in a capped state, then returned to room temperature, and filtered through a 0.5 μm membrane filter. Then, a carrier mobility μ_{cold} determined by calculating a carrier mobility in the same manner as in (a) was divided by a carrier mobility μ measured by a common method, and the obtained value (μ_{cold/}μ) was evaluated into 5 levels as below. The greater the value, the higher the preservation stability of the coating solution. For practical use, the value is preferably S, A, or B, more preferably S or A, and particularly preferably S.

S:μ_{cold}/μ>0.95

A:0.70<μ_{cold}/μ≦0.95

B:0.50<μ_{cold}/μ≦0.70

C:0.10<μ_{cold}/μ≦0.50

D:μ_{cold}/μ≦0.10

The following Table 1 shows the results obtained in a case where the composition for forming an organic semiconductor film was applied by spin coating method. Table 2 shows the results obtained in a case where the composition for forming an organic semiconductor film was applied by ink jet printing or flexographic printing.

TABLE 1

| | | | | | Concentration | | | |
|---|---|---|---|---|---|---|---|---|
| | | | | | Organic | | | |
| | | | | | semiconductor/ | Carrier | Threshold | Mobility |
| | | Organic | Binder | | binder polymer | mobility | voltage | retention |
| | Element No. | semiconductor | polymer | Solvent | (mass %) | (cm²/Vs) | shift | rate |
| Example 1 | Element 1-1 | Compound 1 | — | Tetralin | 1.5 | 4.9 × 10⁻² | S | A |
| Example 2 | Element 1-2 | Compound 2 | — | Tetralin | 1.0 | 4.4 × 10⁻² | S | A |
| Example 3 | Element 1-3 | Compound 2 | PTAA | Tetralin | 1.0/0.5 | 4.3 × 10⁻² | S | A |
| Example 4 | Element 1-4 | Compound 3 | — | Tetralin | 1.5 | 6.3 × 10⁻² | S | A |
| Example 5 | Element 1-5 | Compound 3 | PαMS | Tetralin | 1.5/1.5 | 7.2 × 10⁻² | S | A |
| Example 6 | Element 1-6 | Compound 4 | — | Mesitylene | 1.0 | 9.3 × 10⁻² | S | A |
| Example 7 | Element 1-7 | Compound 4 | — | Cyclohexanone | 1.0 | 7.9 × 10⁻² | S | A |
| Example 8 | Element 1-8 | Compound 5 | — | Diethylbenzene | 1.0 | 2.1 × 10⁻¹ | S | A |
| Example 9 | Element 1-9 | Compound 6 | — | Mesitylene | 2.0 | 1.6 × 10⁻¹ | S | A |
| Example 10 | Element 1-10 | Compound 6 | PCPDTBT | Mesitylene | 2.0/0.50 | 1.6 × 10⁻¹ | S | A |
| Example 11 | Element 1-11 | Compound 7 | — | Anisole | 1.0 | 1.3 × 10⁻² | A | A |
| Example 12 | Element 1-12 | Compound 8 | — | Tetralin | 1.0 | 1.0 × 10⁻¹ | S | A |
| Example 13 | Element 1-13 | Compound 9 | — | Anisole | 1.0 | 7.7 × 10⁻² | S | A |
| Example 14 | Element 1-14 | Compound 9 | — | Tetralin | 1.0 | 7.8 × 10⁻² | S | A |
| Example 15 | Element 1-15 | Compound 10 | — | Anisole | 1.0 | 2.4 × 10⁻¹ | S | A |
| Example 16 | Element 1-16 | Compound 10 | — | Anisole | 5.0 | 3.6 × 10⁻¹ | S | A |
| Example 17 | Element 1-17 | Compound 10 | — | Anisole | 7.5 | 3.4 × 10⁻¹ | S | A |
| Example 18 | Element 1-18 | Compound 11 | — | Tetralin | 1.5 | 4.0 × 10⁻² | A | A |
| Example 19 | Element 1-19 | Compound 12 | — | Tetralin | 1.0 | 5.1 × 10⁻² | S | A |
| Example 20 | Element 1-20 | Compound 12 | — | N-methylpyrrolidone | 1.0 | 3.3 × 10⁻² | S | A |
| Example 21 | Element 1-21 | Compound 13 | — | Tetralin | 1.0 | 3.5 × 10⁻² | S | A |
| Example 22 | Element 1-22 | Compound 14 | — | Anisole | 0.7 | 1.4 × 10⁻¹ | S | A |
| Example 23 | Element 1-23 | Compound 14 | — | Tetralin | 0.7 | 1.4 × 10⁻¹ | S | A |
| Example 24 | Element 1-24 | Compound 14 | — | Tetralin | 3.0 | 2.3 × 10⁻¹ | S | A |
| Example 25 | Element 1-25 | Compound 15 | — | Anisole | 1.0 | 9.1 × 10⁻² | S | A |
| Example 26 | Element 1-26 | Compound 15 | PαMS | Anisole | 1.0/0.75 | 9.7 × 10⁻² | S | A |
| Example 27 | Element 1-27 | Compound 16 | — | Anisole | 0.7 | 9.8 × 10⁻² | S | A |
| Example 28 | Element 1-28 | Compound 16 | PCPDTBT | Anisole | 0.7/0.7 | 9.9 × 10⁻² | S | A |
| Example 29 | Element 1-29 | Compound 17 | — | Tetralin | 1.0 | 7.2 × 10⁻² | A | A |
| Example 30 | Element 1-30 | Compound 18 | — | Tetralin | 1.0 | 2.9 × 10⁻² | S | A |
| Example 31 | Element 1-31 | Compound 18 | PTAA | Tetralin | 1.0/1.0 | 3.3 × 10⁻² | S | A |
| Example 32 | Element 1-32 | Compound 19 | — | Anisole | 1.0 | 1.8 × 10⁻² | A | A |
| Example 33 | Element 1-33 | Compound 10 | — | Anisole/ | 1.0 | 1.9 × 10⁻¹ | A | A |
| | | | | chlorobenzene = 2/1 | | | | |
| Comparative | Element 1-34 | Compound 10 | — | Anisole/ | 1.0 | 2.3 × 10⁻¹ | C | A |
| Example 1 | | | | chlorobenzene = 1/2 | | | | |
| Comparative | Element 1-35 | Compound 10 | — | Chloroform | 1.0 | 9.4 × 10⁻² | D | A |
| Example 2 | | | | | | | | |
| Comparative | Element 1-36 | Compound 10 | — | Chlorobenzene | 1.0 | 2.0 × 10⁻¹ | D | A |
| Example 3 | | | | | | | | |
| Comparative | Element 1-37 | Compound 14 | — | Tetralin | 0.5 | 2.9 × 10⁻² | B | A |
| Example 4 | | | | | | | | |
| Comparative | Element 1-38 | Compound 14 | — | Tetralin | 0.3 | 1.6 × 10⁻² | B | A |
| Example 5 | | | | | | | | |
| Comparative | Element 1-39 | Comparative | — | Anisole | 1.0 | 3.5 × 10⁻⁵ | D | B |
| Example 6 | | compound 1 | | | | | | |
| Comparative | Element 1-40 | Comparative | — | Anisole | 1.0 | 1.9 × 10⁻⁵ | D | B |
| Example 7 | | compound 2 | | | | | | |
| Comparative | Element 1-41 | Comparative | — | Tetralin | 1.0 | 8.2 × 10⁻⁵ | B | C |
| Example 8 | | compound 3 | | | | | | |
| Comparative | Element 1-42 | Comparative | — | Anisole | 1.0 | 1.7 × 10⁻⁴ | B | D |
| Example 9 | | compound 4 | | | | | | |
| Comparative | Element 1-43 | Comparative | — | Anisole | 1.0 | 7.3 × 10⁻⁴ | D | D |
| Example 10 | | compound 5 | | | | | | |
| Comparative | Element 1-44 | Comparative | — | Tetralin | 1.0 | 2.2 × 10⁻⁴ | C | C |
| Example 11 | | compound 6 | | | | | | |
| Comparative | Element 1-45 | Comparative | — | Tetralin | 2.0 | 2.9 × 10⁻⁴ | D | D |
| Example 12 | | compound 6 | | | | | | |
| Comparative | Element 1-46 | Comparative | — | Anisole | 0.5 | 1.1 × 10⁻² | B | D |
| Example 13 | | compound 7 | | | | | | |
| Comparative | Element 1-47 | Comparative | — | Anisole | 1.0 | 2.7 × 10⁻⁵ | D | C |
| Example 14 | | compound 8 | | | | | | |

TABLE 2

| | | | | | Concentration | | | |
|---|---|---|---|---|---|---|---|---|
| | | | | | Organic | | | |
| | | | | | semiconductor/ | | Carrier | Threshold |
| | | Organic | Binder | | binder polymer | Application | mobility | voltage |
| | Element No. | semiconductor | polymer | Solvent | (mass %) | method | (cm²/Vs) | shift |
| Example 34 | Element 2-1 | Compound 1 | PCPDTBT | Anisole | 1.0/1.0 | Ink jet | 7.1 × 10⁻² | S |
| Example 35 | Element 2-2 | Compound 2 | PCPDTBT | Tetraln | 2.0/2.0 | Flexography | 5.8 × 10⁻² | S |
| Example 36 | Element 2-3 | Compound 3 | — | Toluene | 2.0 | Ink jet | 8.1 × 10⁻² | S |
| Example 37 | Element 2-4 | Compound 3 | — | Mesitylene | 2.0 | Ink jet | 9.6 × 10⁻² | S |
| Example 38 | Element 2-5 | Compound 3 | — | Anisole | 2.0 | Ink jet | 1.2 × 10⁻¹ | S |
| Example 39 | Element 2-6 | Compound 3 | — | Tetralin | 2.0 | Ink jet | 1.3 × 10⁻¹ | S |
| Example 40 | Element 2-7 | Compound 4 | — | Tetralin | 5.0 | Ink jet | 3.3 × 10⁻¹ | S |
| Example 41 | Element 2-8 | Compound 5 | PCPDTBT | Tetralin | 1.0/0.5 | Ink jet | 5.1 × 10⁻¹ | S |
| Example 42 | Element 2-9 | Compound 5 | PCPDTBT | Tetralin | 1.5/0.5 | Ink jet | 6.2 × 10⁻¹ | S |
| Example 43 | Element 2-10 | Compound 6 | PαMS | Tetralin | 7.5/2.5 | Flexography | 1.5 × 10⁻¹ | S |
| Example 44 | Element 2-11 | Compound 10 | PαMS | Tetralin | 2.0/2.0 | Flexography | 4.7 × 10⁻¹ | S |
| Example 45 | Element 2-12 | Compound 12 | PCPDTBT | Tetralin | 2.0/0.5 | Ink jet | 6.8 × 10⁻² | S |
| Example 46 | Element 2-13 | Compound 14 | PαMS | Anisole | 1.0/0.5 | Flexography | 2.4 × 10⁻¹ | S |
| Example 47 | Element 2-14 | Compound 14 | PαMS | Anisole | 1.0/1.0 | Flexography | 3.0 × 10⁻¹ | S |
| Example 48 | Element 2-15 | Compound 15 | PTAA | Tetralin | 1.0/1.0 | Ink jet | 3.5 × 10⁻¹ | S |
| Example 49 | Element 2-16 | Compound 17 | PCPDTBT | Tetralin | 1.5/0.50 | Ink jet | 1.2 × 10⁻¹ | S |
| Example 50 | Element 2-17 | Compound 18 | PTAA | Tetralin | 2.5/2.0 | Flexography | 4.1 × 10⁻² | S |

As shown in Tables 1 and 2, it was confirmed that the composition for forming an organic semiconductor film of the present invention has excellent preservation stability, makes the obtained organic semiconductor exhibit excellent driving stability in the atmosphere, and has high carrier mobility.

In contrast, the compositions for forming an organic semiconductor film of comparative examples failed to achieve both of the preservation stability and the performance of making the obtained organic semiconductor exhibit driving stability in the atmosphere.

### EXPLANATION OF REFERENCES

10: substrate

20: gate electrode

30: gate insulating film

40: source electrode

42: drain electrode

50: organic semiconductor film

51: metal mask

52: mask portion

53, 54: opening portion

60: sealing layer

100, 200: organic thin film transistor

What is claimed is:

1. A composition for forming an organic semiconductor film, comprising:
an organic semiconductor represented by the following Formula A-1 as a component A; and
a solvent as a component B,
wherein a content of a non-halogen-based solvent is equal to or greater than 50% by mass with respect to a total content of the component B, and
a content of the component A is equal to or greater than 0.7% by mass and less than 15% by mass,
TLₘ-Z)ₙ (A-1)
in Formula A-1, T represents an aromatic hydrocarbon group having a ring-fused structure including 3 or more rings or a heteroaromatic group; L each independently represents a phenylene group or a thienylene group; Z each independently represents a group represented by the following Formula a-1; m each independently represents an integer of 0 to 4, n represents an integer of 1 to 8; and in a case where T is a group having a ring-fused structure including 3 or 4 rings, m represents an integer of 1 to 4, and n represents an integer of 2 to 8, 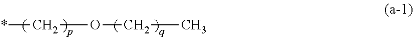
in Formula a-1, p represents an integer of 1 to 20, q represents an integer of 0 to 20, and * represents a binding position with respect to other structures.

2. The composition for forming an organic semiconductor film according to claim 1,
wherein in Formula A-1, T contains an acene, phenacene, or heteroacene structure having a ring-fused structure including 3 to 7 rings.

3. The composition for forming an organic semiconductor film according to claim 1,
wherein the component A is an organic semiconductor represented by the following Formula A-2, 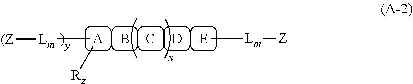
in Formula A-2, rings A to E each independently represent a benzene ring or a thiophene ring; R represents an alkyl group, an alkenyl group, an alkynyl group, an aromatic hydrocarbon group, an aromatic heterocyclic group, or a fluorine atom; L each independently represents a phenylene group or a thienylene group; Z each independently represents a group represented by Formula a-1; m each independently represents an integer of 0 to 4; when there are two or more L's, L's may be the same as or different from each other; when there are two or more Z's, Z's may be the same as or different from each other; x represents an integer of 1 to 3; y represents 0 or 1; z represents 0 or 1; and the symmetry of a ring-fused structure formed of the rings A to E is C₂, C₂ᵥ, or C₂ₕ.

4. The composition for forming an organic semiconductor film according to claim 3,
wherein 2 to 4 rings among the rings A to E are thiophene rings.

5. The composition for forming an organic semiconductor film according to claim 3,
wherein the rings A and E are thiophene rings and/or L is a thienylene group, and m is an integer of 1 to 4.

6. The composition for forming an organic semiconductor film according to claim 1,
wherein in Formula a-1, p is an integer of 1 to 6.

7. The composition for forming an organic semiconductor film according to claim 1,
wherein a boiling point of the non-halogen-based solvent is equal to or higher than 100° C.

8. The composition for forming an organic semiconductor film according to claim 1,
wherein the non-halogen-based solvent contains an aromatic solvent in an amount of equal to or greater than 50% by mass.

9. The composition for forming an organic semiconductor film according to claim 1 that has a viscosity of equal to or higher than 5 mPa·s and equal to or lower than 40 mPa·s at 25° C.

10. The composition for forming an organic semiconductor film according to claim 1, further comprising:
a binder polymer as a component C.

11. The composition for forming an organic semiconductor film according to claim 1,
wherein a concentration of total solid contents is equal to or higher than 1.5% by mass.

12. The composition for forming an organic semiconductor film according to claim 1 that is used for ink jet printing and/or flexographic printing.

13. A method for manufacturing an organic semiconductor film, comprising:
an application step of applying the composition for forming an organic semiconductor film according to claim 1 onto a substrate; and
a drying step of removing a solvent from the applied composition.

14. A method for manufacturing an organic semiconductor element, comprising:
an application step of applying the composition for forming an organic semiconductor film according to claim 1 onto a substrate; and
a drying step of removing a solvent from the applied composition.

15. The method for manufacturing an organic semiconductor element according to claim 14, wherein the application step is performed by ink jet printing or flexographic printing.

16. An organic semiconductor compound represented by Formula A-2, 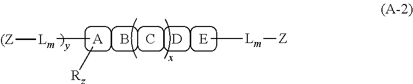
in Formula A-2, rings A to E each independently represent a benzene ring or a thiophene ring; R represents an alkyl group, an alkenyl group, an alkynyl group, an aromatic hydrocarbon group, an aromatic heterocyclic group, or a fluorine atom; L each independently represents a phenylene group or a thienylene group; Z each independently represents a group represented by the following Formula a-1; m each independently represents an integer of 0 to 4; when there are two or more L's, L's may be the same as or different from each other; when there are two or more Z's, Z's may be the same as or different from each other; x represents an integer of 1 to 3; y represents 0 or 1; z represents 0 or 1; and the symmetry of a ring-fused structure formed of the rings A to E is C₂, C₂ᵥ, or C₂ₕ, 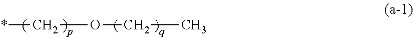
in Formula a-1, p represents an integer of 1 to 20, q represents an integer of 0 to 20, and * represents a binding position with respect to other structures.

17. The organic semiconductor compound according to claim 16,
wherein 2 to 4 rings among the rings A to E are thiophene rings.

18. The organic semiconductor compound according to claim 16,
wherein the rings A and E are thiophene rings and/or L is a thienylene group, and m is an integer of 1 to 4.

19. The organic semiconductor compound according to claim 16, wherein in Formula a-1, p is an integer of 1 to 6.
